(19) United States
(12) Patent Application Publication
(10) Pub. No.: US 2026/0178155 A1
(43) Pub. Date: Jun. 25, 2026

(54) DISPLAY PANEL AND DISPLAY DEVICE

(71) Applicants: Hefei BOE Ruisheng Technology Co., Ltd., Hefei, Anhui (CN); BOE Technology Group Co., Ltd., Beijing (CN)

(72) Inventors: Jiawei XU, Beijing (CN); Zouming XU, Beijing (CN); Ting ZENG, Beijing (CN); Xintao WU, Beijing (CN); Tao XIAO, Beijing (CN)

(73) Assignees: Hefei BOE Ruisheng Technology Co., Ltd., Hefei, Anhui (CN); BOE Technology Group Co., Ltd., Beijing (CN)

(21) Appl. No.: 18/729,171

(22) PCT Filed: Apr. 28, 2023
(86) PCT No.: PCT/CN2023/091662

§ 371 Date: Jul. 16, 2024

(51) Int. Cl. G06F 3/044

(52) U.S. Cl. CPC G06F 3/0446

(57) ABSTRACT

Provided is a display panel, including: a substrate; a driving layer, wherein the driving layer includes a plurality of conductive pads; a light-absorbing layer disposed on a side, away from the substrate, of the driving layer, wherein an orthographic projection of the light-absorbing layer on the substrate is overlapped with an orthographic projection of the driving layer on the substrate, and a plurality of first vias corresponding to the plurality of conductive pads are formed in the light-absorbing layer, an orthographic projection of each of the first vias on the substrate is overlapped with an orthographic projection of a corresponding one of the conductive pads on the substrate; and a plurality of light-emitting units disposed on a side, away from the substrate, of the light-absorbing layer, wherein the plurality of light-emitting units are electrically connected to at least a portion of the conductive pads by the first vias.

### CROSS-REFERENCE TO RELATED APPLICATION

The application is a U.S. national stage of international application No. PCT/CN2023/091662, filed on Apr. 28, 2023, the content of which is herein incorporated by reference in its entirety.

### TECHNICAL FIELD

The present disclosure relates to the field of display technologies, and in particular, relates to a display panel and a display device.

### BACKGROUND

With the developments in the field of display technology, LED display panels become a most advantageous new generation of display media and have been widely used due to the advantages of pure chromaticity, wide dynamic range, high brightness, high definition, low operating voltage, low power consumption, long service life, impact resistance, large viewing angle, and stable and reliable operation.

### SUMMARY

Embodiments of the present disclosure provide a display panel and a display device. The technical solutions are as follows.

According to some embodiments of the present disclosure, a display panel is provided. The display panel includes:
a substrate;
a driving layer disposed on a side of the substrate, wherein the driving layer includes a plurality of conductive pads;
a light-absorbing layer disposed on a side, away from the substrate, of the driving layer, wherein an orthographic projection of the light-absorbing layer on the substrate is overlapped with an orthographic projection of the driving layer on the substrate, and a plurality of first vias corresponding to the plurality of conductive pads are formed in the light-absorbing layer, an orthographic projection of each of the first vias on the substrate is overlapped with an orthographic projection of a corresponding one of the conductive pads on the substrate; and
a plurality of light-emitting units disposed on a side, away from the substrate, of the light-absorbing layer, wherein the plurality of light-emitting units are electrically connected to at least a portion of the conductive pads by the first vias.

In some embodiments, within a display region of the display panel, the orthographic projection of the light-absorbing layer on the substrate covers an orthographic projection of a portion, other than the conductive pads, of the driving layer on the substrate.

In some embodiments, the display panel further includes a first insulating layer disposed on the side, away from the substrate, of the light-absorbing layer, wherein a plurality of second vias in one-to-one correspondence with the plurality of first vias are formed in the first insulating layer, each of the second vias being communicated to a corresponding one of the first vias;
wherein each of the light-emitting units is electrically connected to the conductive pad by the second via and the first via.

In some embodiments, a portion of the first insulating layer extends into the first via and covers at least a portion of an inner wall of the first via; and
the first insulating layer includes at least one of an inorganic insulating layer or an organic insulating layer.

In some embodiments, the light-absorbing layer includes charcoal particles; and the inner wall of the first via is completely covered by the first insulating layer.

In some embodiments, the first insulating layer includes both the inorganic insulating layer and the organic insulating layer, the inorganic insulating layer being closer to the light-absorbing layer relative to the organic insulating layer; and
a portion of the inorganic insulating layer extends into the first via and covers the inner wall of the first via, and/or, a portion of the organic insulating layer extends into the first via and covers the inner wall of the first via.

In some embodiments, the first insulating layer includes both the inorganic insulating layer and the organic insulating layer, the organic insulating layer being closer to the light-absorbing layer relative to the inorganic insulating layer; and
a portion of the inorganic insulating layer extends into the first via and covers the inner wall of the first via, and/or, a portion of the organic insulating layer extends into the first via and covers the inner wall of the first via.

In some embodiments, a thickness of the light-absorbing layer ranges from 0.5 microns to 5 microns.

In some embodiments, an optical density (OD) of the light-absorbing layer is greater than or equal to 4.

In some embodiments, the driving layer includes a first metal layer and a second metal layer that are stacked; and the display panel further includes a second insulating layer disposed between the first metal layer and the second metal layer, the first metal layer being closer to the substrate relative to the second metal layer; wherein
the first metal layer includes a plurality of first driving signal lines, and the second metal layer includes a second driving signal line and the plurality of conductive pads, wherein an extension direction of each of the first driving signal lines is intersected with an extension direction of the second driving signal line; and
in the plurality of conductive pads, a portion of the conductive pads is electrically connected to the second driving signal line, and another portion of the conductive pads is electrically connected to the first driving signal line.

In some embodiments, the light-absorbing layer includes an organic film layer made of an organic material with a light-absorbing property.

In some embodiments, an edge region of a side, away from the driving layer, of the substrate includes a bonding region, and the display panel further includes a plurality of signal leads disposed in the bonding region, at least a portion of the plurality of signal leads being electrically connected to the plurality of first driving signal lines;
wherein an auxiliary via is formed in a portion, covered by the bonding region, of the light-absorbing layer; the display panel includes a blank region, wherein the blank region is a region, not covered by the first metal layer and the second metal layer, within the bonding region; and an orthographic projection of the auxiliary via on the substrate is overlapped with an orthographic projection of the blank region on the substrate.

In some embodiments, the orthographic projection of the auxiliary via on the substrate covers the orthographic projection of the blank region on the substrate; or the orthographic projection of the blank region on the substrate covers the orthographic projection of the auxiliary via on the substrate.

In some embodiments, the plurality of light-emitting units are arranged in a plurality of columns, the plurality of first driving signal lines include a plurality of groups of the first driving signal lines corresponding to the plurality of columns of the light-emitting units, and each group of the plurality of groups of the first driving signal lines is electrically connected to each of the light-emitting units in a corresponding column of the plurality of columns of the light-emitting units; and
the auxiliary vias are at least disposed between adjacent two groups of the first driving signal lines and adjacent two of the second driving signals.

In some embodiments, one group of the first driving signal lines includes a grounding line, and the second metal layer further includes an auxiliary grounding line arranged in parallel with the second driving signal line, wherein the auxiliary grounding line is electrically connected to the grounding line, and an orthographic projection of the auxiliary grounding line on the substrate is overlapped with an orthographic projection of the bonding region on the substrate;
wherein one of the auxiliary grounding lines and the adjacent second driving signal line are both disposed between two rows of the light-emitting units, and the auxiliary via is further disposed between adjacent two groups of the first driving signal lines and one of the auxiliary lines and the adjacent second driving signal line.

In some embodiments, the display panel further includes a plurality of connecting traces correspondingly electrically connected to the plurality of signal leads, wherein one portion of the plurality of connecting traces is disposed on a side, close to the driving layer, of the substrate, and the other portion of the plurality of connecting traces is disposed on a side surface of the substrate;
wherein the plurality of connecting traces and the plurality of signal leads are formed by a same process.

In some embodiments, the light-absorbing layer is conductive; and the light-absorbing layer includes a metal reflecting layer, and a first blackening layer is disposed on a side, away from the substrate, of the metal reflecting layer.

In some embodiments, the light-absorbing layer includes a plurality of auxiliary signal lines corresponding to the plurality of first driving signal lines, wherein a first gap is present between adjacent two of the auxiliary signal lines, each of the auxiliary signal lines and a corresponding one of the first driving signal lines extends along a same direction, each of the auxiliary signal lines is connected in parallel with a corresponding one of the first driving signal lines.

In some embodiments, a plurality of connecting vias are formed in the display panel, wherein the plurality of connecting vias are at least disposed on two opposite sides of the plurality of auxiliary signal lines, one end of each of the auxiliary signal lines is electrically connected to a corresponding one of the first driving signal lines by at least one of the connecting vias, and the other end of each of the auxiliary signal lines is electrically connected to a corresponding one of the first driving signal lines by at least one of the connecting vias.

In some embodiments, the light-absorbing layer includes a plurality of first touch signal lines arranged in parallel, a second gap being present between adjacent two of the first touch signal lines; and
the display panel further includes a first insulating layer disposed on the side, away from the substrate of the light-absorbing layer, and a plurality of second touch signal lines disposed on a side, away from the substrate, of the first insulating layer, wherein an extension direction of each of the second touch signal lines is intersected with an extension direction of each of the first touch signal lines.

In some embodiments, at least a portion of the second touch signal lines are grid-like metal signal lines.

In some embodiments, the display panel further includes: virtual signal lines disposed between adjacent two of the second touch signal lines, wherein at least a portion of the virtual signal lines are grid-like metal signal lines, and the virtual signal lines and the second driving signal lines are disposed in a same layer and made of a same material.

In some embodiments, each of the second touch signal line and the virtual signal line includes a conductive metal layer and a second blackening layer that are stacked, the conductive metal layer being closer to the substrate relative to the second blackening layer.

In some embodiments, a hollowed-out structure is formed in at least one of the second touch signal line or the virtual signal line, an orthographic projection of the hollowed-out structure on the substrate covering the orthographic projection of the first via on the substrate.

In some embodiments, the light-absorbing layer further includes an auxiliary metal layer disposed between the metal reflecting layer and the first blackening layer, wherein a conductivity of the auxiliary metal layer is greater than a conductivity of the metal reflecting layer, and a reflectivity of the metal reflecting layer is greater than a reflectivity of the auxiliary metal layer.

In some embodiments, the display panel further includes a plurality of driver chips, wherein the plurality of driver chips are electrically connected to one or more of the light-emitting units;
wherein the plurality of conductive pads include a first pad group configured to be fixedly connected to the light-emitting units, and a second pad group configured to be fixedly connected to the driver chips.

In some embodiments, the first pad group includes a first conductive pad and a second conductive pad, and the second pad group includes a third conductive pad, a fourth conductive pad, and a fifth conductive pad; wherein
one portion of the plurality of first driving signal lines is electrically connected to the first conductive pad, the second conductive pad is electrically connected to the third conductive pad, another portion of the plurality of first driving signal lines is electrically connected to the fourth conductive pad, and the second driving signal line is electrically connected to the fifth conductive pad.

In some embodiments, the display panel further includes an auxiliary light-absorbing layer disposed on a side, away from the substrate, of the plurality of light-emitting units, wherein the auxiliary light-absorbing layer covers the driver chips and the light-emitting units simultaneously.

According to some embodiments of the present disclosure, a display device is provided. The display device includes a driving assembly and the display panel as described above;
wherein the driving assembly is electrically connected to a driving layer, and the driving assembly is configured to provide driving signals to light-emitting units through the driving layer.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a top view of a display panel according to some embodiments of the present disclosure;

FIG. 2 is a schematic diagram of a film layer structure of the display panel illustrated in FIG. 1 along a line A-A′;

FIG. 3 is a sketch of a film layer structure of a display panel according to some embodiments of the present disclosure;

FIG. 4 is a schematic diagram of a film layer structure of a driving backplane in a display panel according to some embodiments of the present disclosure;

FIG. 5 is a schematic diagram of a film layer structure of a driving backplane in another display panel according to some embodiments of the present disclosure;

FIG. 6 is a schematic diagram of a film layer structure of a driving backplane in yet another display pane according to some embodiments of the present disclosure;

FIG. 7 is a schematic diagram of a film layer structure of a driving backplane in yet still another display panel according to some embodiments of the present disclosure;

FIG. 8 is a partial top view of a driving backplane in a display panel according to some embodiments of the present disclosure;

FIG. 9 is a partial top view of a display panel according to some embodiments of the present disclosure;

FIG. 10 is a backside schematic diagram of a display panel according to some embodiments of the present disclosure;

FIG. 11 is a side schematic diagram of the display panel illustrated in FIG. 10;

FIG. 12 is a partial top view of a display panel according to some embodiments of the present disclosure;

FIG. 13 is a partial top view of another display panel according to some embodiments of the present disclosure;

FIG. 14 is a partial top view of the display panel illustrated in FIG. 13 with a light-absorbing layer removed;

FIG. 15 is a schematic diagram of a film layer structure of a light-absorbing layer according to some embodiments of the present disclosure;

FIG. 16 is a partial top view of a display panel according to some embodiments of the present disclosure;

FIG. 17 is a schematic diagram of a film layer structure of the display panel illustrated in FIG. 16 along a line B-B′;

FIG. 18 is a partial top view of another display panel according to some embodiments of the present disclosure;

FIG. 19 is a schematic diagram of a film layer structure of the display panel illustrated in FIG. 18;

FIG. 20 is a top view of a plurality of second touch signal lines according to some embodiments of the present disclosure;

FIG. 21 is a schematic diagram of a film layer structure of a second touch signal line or a virtual signal line according to some embodiments of the present disclosure; and

FIG. 22 is a partially enlarged view of a second touch signal line and a virtual signal line according to some embodiments of the present disclosure.

### DETAILED DESCRIPTION

The present disclosure is described in further detail with reference to the accompanying drawings, to clearly present the objects, technical solutions, and advantages of the present disclosure.

In the related art, to reduce the reflectivity of the LED display panel to ambient light, it is often necessary to provide a black film in the LED display panel. For example, in the LED display panel, the black film is disposed on one side, away from the driving backplane, of the plurality of LEDs. In this way, a portion of the ambient light directed to the LED display panel is absorbed by the black film, such that less ambient light, directed to the LED display panel, is reflected by the metal signal lines in the driving backplane.

However, to reduce the reflectivity of the ambient light by the LED display panel, it is necessary to ensure that the black film absorbs the light at a high rate. In a case where the absorbance of light by the black film is high, the transmittance of the black film is low. For example, the transmittance of the black film is typically less than 30%, such that the black film also has a high absorbance of light exiting from the LEDs. For this reason, the driving backplane needs to supply a higher current to the LEDs to ensure that the overall display brightness of the LEDs is higher, and thus the power consumption of the LED display panel is high.

At present, an LED display panel typically includes a driving backplane and a plurality of LEDs disposed on a side of the driving backplane. The driving backplane is capable of transmitting a driving signal to each of the LEDs, such that the LEDs are capable of emitting light of corresponding colors, and thus the LED display panel is capable of presenting corresponding display images.

However, the driving backplane usually includes a plurality of metal signal lines, and the metal signal lines have a higher reflectivity to ambient light. Therefore, the current LED display panels are highly susceptible to reflecting ambient light, leading to a poor display effect of the LED display panels.

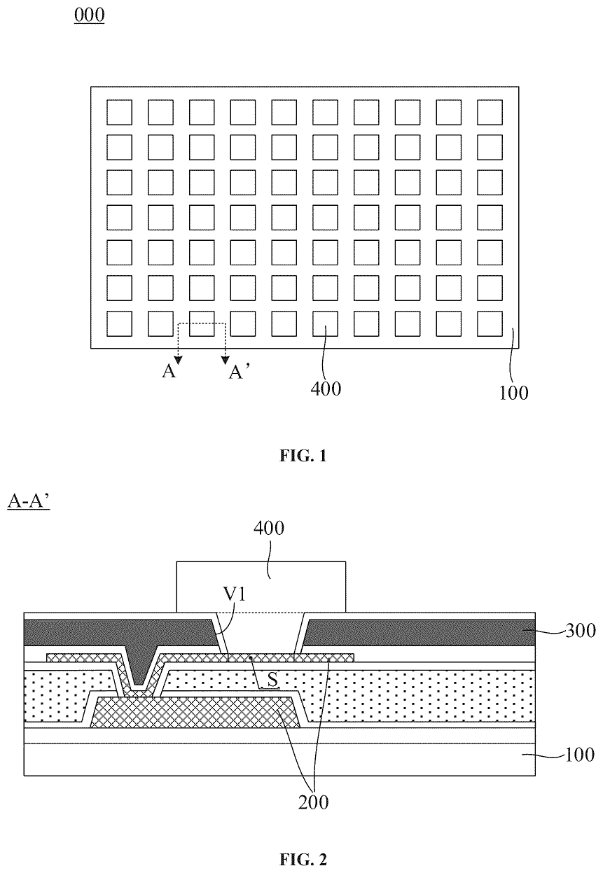

FIG. 1 is a top view of a display panel according to some embodiments of the present disclosure. FIG. 2 is a schematic diagram of a film layer structure of the display panel illustrated in FIG. 1 along a line A-A′. Referring to FIG. 1 and FIG. 2, the display panel 000 includes a substrate 100, a driving layer 200, a light-absorbing layer 300, and a plurality of light-emitting units 400.

The driving layer 200 in the display panel 000 is disposed on a side of the substrate 100, and the driving layer 200 has a plurality of conductive pads S. Here, the driving layer 200 includes a metal signal line with a high reflectivity.

The light-absorbing layer 300 in the display panel 000 is disposed on a side, away from the substrate 100, of the driving layer 200. In this case, an overlapped region is present between an orthographic projection of the light-absorbing layer 300 on the substrate 100 and an orthographic projection of the driving layer 200 on the substrate 100. In this way, the light-absorbing layer 300 is capable of absorbing the ambient light directed to the display panel 000, such that less ambient light directed to the display panel 000 is reflected by the driving layer 200, and thus the reflectivity of the display panel 000 to the ambient light is low. Moreover, the light-absorbing layer 300 in the display panel 000 has a plurality of first vias V1 therein corresponding to the plurality of conductive pads S, and an orthographic projection of each first via V1 on the substrate 100 is overlapped with an orthographic projection of the corresponding conductive pad S on the substrate 100. For example, the orthographic projection of each first via V1 on the substrate 100 is within the orthographic projection of the corresponding conductive pad S on the substrate 100, which ensures that the light-absorbing layer 300 does not shield the conductive pads S, and thus the conductive pads S are subsequently electrically connected to the light-emitting units 400.

Exemplarily, within a display region of the display panel 000, the orthographic projection of the light-absorbing layer 300 in the display panel 000 on the substrate 100 covers an orthographic projection of a portion of the driving layer 200 other than the conductive pads S on the substrate 100. That is, within the display region of the display panel 000, the portion of the driving layer 200 other than the conductive pads S is shielded by the light-absorbing layer 300. It should be noted that the display region of the display panel 000 refers to a region in a front face of the display panel 000 in which images are displayed. Typically, the front face of the display panel 000 also includes a non-display region surrounding the display region. In some possible embodiments, the light-absorbing layer 300 in the display panel 000 is within the non-display region of the display panel 000.

The conductive pads S in the driving layer 200 need to be connected to the light-emitting units 400, and the conductive pads are capable of being shielded by the light-emitting unit 400. The portion of the driving layer 200 other than the conductive pads S is a metal portion with the high reflectivity and is not shielded by the light-emitting units 400. Thus, in a case where the light-absorbing layer 300 covers the portion of the driving layer 200 other than the conductive pads S, the overall reflectivity of the display panel 000 is further reduced.

The plurality of light-emitting units 400 in the display panel 000 are all disposed on a side, away from the substrate 100, of the light-absorbing layer 300. Here, the light-emitting units 400 are electrically connected to at least a portion of the conductive pads S by the first vias V1, such that the driving layer 300 in the display panel 000 drives the light-emitting units 400 to emit light by the conductive pads S. It should be noted that a portion, disposed below the plurality of light-emitting units 400, of the display panel 000 is a driving backplane in the display panel 000. That is, the driving backplane includes the substrate 100, and the driving layer 200 and the light-absorbing layer 300 disposed on a side of the substrate 100. The plurality of light-emitting units 400 in the display panel 000 are all provided on the driving backplane. Here, below the plurality of light-emitting units 400 refers to a side opposite to a light-exiting direction of the plurality of light-emitting units 400.

In some possible embodiments, the light-emitting units 400 in the display panel 000 are LEDs. In other possible embodiments, the light-emitting units 400 in the display panel 000 include LEDs and driver chips electrically connected to the LEDs. Here, the driver chip controls the LEDs to emit light and controls the luminance of the LEDs. The following embodiments all give the description using a scenario where the light-emitting units 400 includes both the LEDs and the driver chips as an example.

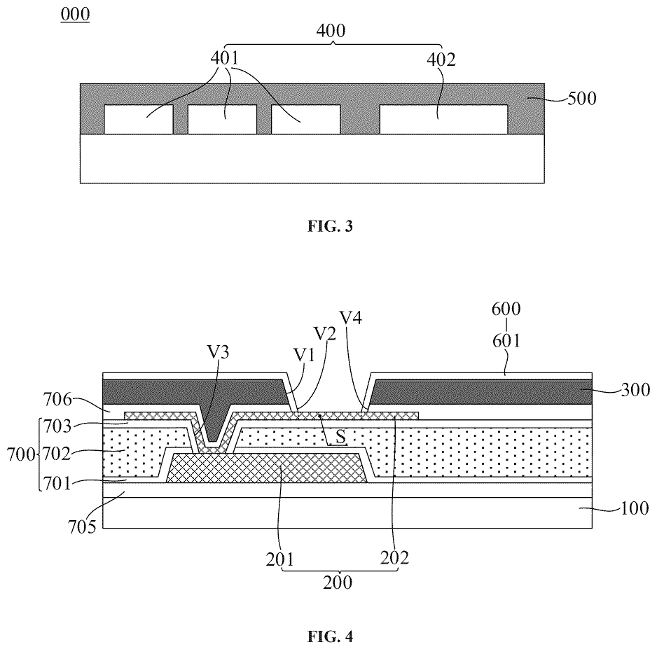

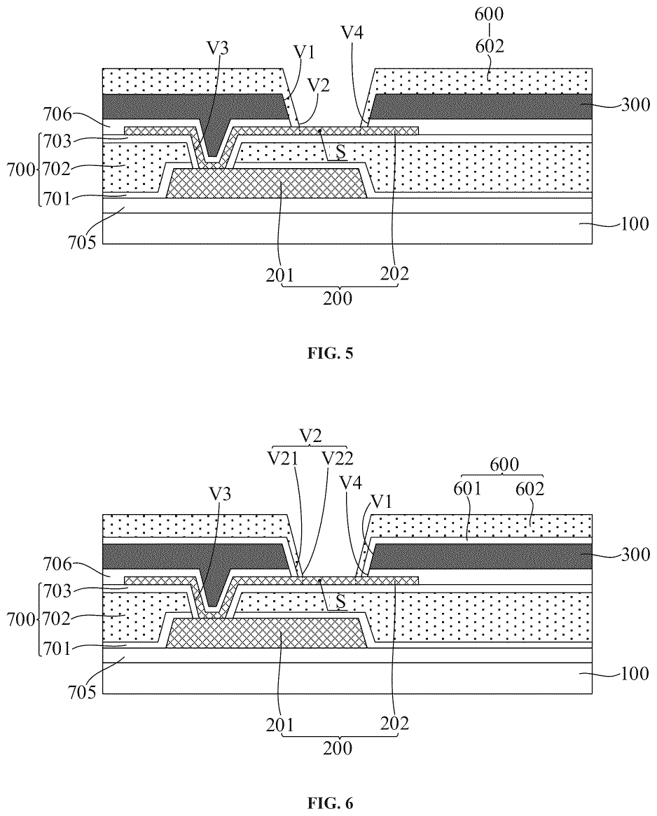

FIG. 3 is a sketch of a film layer structure of a display panel according to some embodiments of the present disclosure. As shown in FIG. 3, the light-emitting unit 400 in the display panel 000 includes an LED 401 and a driver chip 402. Here, both the LED 401 and the driver chip 402 need to be electrically connected to the driving layer 300 in the display panel 000 by the conductive pads S. It should be noted that the LED 401 is a normal-sized LED, a mini light-emitting diode (mini-LED), or a micro-LED.

Due to a large difference between the color of an outer surface of the LED 401 and the color of an outer surface of the driver chip 402, an auxiliary light-absorbing layer 500 needs to be provided in the display panel 000. Here, the auxiliary light-absorbing layer 500 is disposed on a side, away from the substrate 100, of the plurality of light-emitting units 400, and the auxiliary light-absorbing layer 500 covers both the LED 401 and the driver chip 402 in each light-emitting unit 400. It should be noted that the auxiliary light-absorbing layer 500 is also referred to as a black film. In a case where the auxiliary light-absorbing layer 500 covers both the LED 401 and the driver chip 402 at the same time, the outer surface of the LED 401 and the outer surface of the driver chip 402 are made to appear black, and thus the color difference between the outer surface of the LED 401 and the driver chip 402 is effectively eliminated. In some embodiments, in other possible embodiments, instead of providing a separate auxiliary light-absorbing layer 500, the outer surfaces of both the LED 401 and the driver chip 402 are blackened to eliminate the color difference between the two. The embodiments of the present disclosure do not limit this.

In some embodiments of the present disclosure, the reflectivity of the display panel 000 to ambient light is reduced by providing the light-absorbing layer 300 in the display panel 000. Therefore, the transmittance of the auxiliary light-absorbing layer 500 disposed on the side, away from the substrate 100, of the plurality of light-emitting units 400 is appropriately increased, such that the auxiliary light-absorbing layer 500 has a lower absorbance of the light, and thus less light emitted from the light-emitting units 400 is absorbed by the auxiliary light-absorbing layer 500. In this way, there is no need for the display panel 000 to provide a large driving current to the light-emitting unit 400, and the overall display brightness of the display panel 000 is high, and thus the power consumption of the display panel is effectively reduced.

In summary, some embodiments of the present disclosure provide a display panel. The display panel includes the substrate, the driving layer, the light-absorbing layer, and the plurality of light-emitting units. The orthographic projection of the light-absorbing layer on the substrate is overlapped with the orthographic projection of the driving layer on the substrate. In this way, the light-absorbing layer is capable of absorbing the ambient light directed to the display panel, such that the ambient light directed to the display panel reflected by the driving layer is less, and thus the display panel has a lower reflectivity of the ambient light. In addition, the reflectivity of the ambient light of the display panel is reduced by providing the light-absorbing layer in the display panel. Therefore, by appropriately increasing the transmittance of the auxiliary light-absorbing layer disposed on the side, away from the substrate, of the plurality of light-emitting units, the auxiliary light-absorbing layer has a lower absorbance of the light, such that the light emitted from the light-emitting units is absorbed to a lower extent by the auxiliary light-absorbing layer. In this way, without the need for the display panel to provide a larger driving current to the light-emitting unit, the overall display brightness of the display panel is high, and thus the power consumption of the display panel is effectively reduced.

It should be noted that the reflectivity of the display panel 000 is effectively reduced by providing the light-absorbing layer 400 in the display panel 000, such that the display panel 000 is capable of using the auxiliary light-absorbing layer 500 with a higher transmittance. By using the auxiliary light-absorbing layer 500 with a higher transmittance, the power consumption of the display panel 000 is effectively reduced. For example, refer to Table 1, which is a comparison between the display panel illustrated in the present disclosure and the related panel in the related art.

TABLE 1

| | Display | Display | Display | Display |
|---|---|---|---|---|
| | panel 1 | panel 2 | panel 1 | panel 2 |
| | shown in | shown in | shown in | shown in |
| | the related | the related | the present | the present |
| | art | art | disclosure | disclosure |
| Brightness (nit) | 500 | 500 | 500 | 500 |
| Transmittance of | 26% | 24% | 35% | 45% |
| black film | | | | |
| Peak power | 240 | 438 | 307 | 275 |
| consumption | | | | |
| (W/m²□ | | | | |

In the display panel the related art, the black film needs to have a high absorbance of light, such that the metal signal lines in the display panel are better shielded. For example, the black film has a transmittance of light of only about 25%. However, in some embodiments of the present disclosure, since the light-absorbing layer 300 is separately provided in the display panel 000 to shield the metal signal lines in the driving layer 200, there is no need to ensure that the black film (i.e., the auxiliary light-absorbing layer 500) has a high absorbance of light, such that the auxiliary light-absorbing layer 500 has a high transmittance of light. For example, the transmittance of the auxiliary light-absorbing layer 500 of light ranges from 34% to 60%. In this way, the transmittance of the auxiliary light-absorbing layer 500 to the light in the present disclosure is ensured to be significantly higher than the transmittance of the black film to the light in the related art. In this way, in a case where the display panel illustrated in the present disclosure and the display panel illustrated in the related art display an image of the same brightness, the power consumption of the display panel in the present disclosure is significantly lower than the power consumption of the display panel in the related art.

FIG. 4 is a schematic diagram of a film layer structure of a driving backplane in a display panel according to some embodiments of the present disclosure. Optionally, as shown in FIG. 4, the driving backplane in the display panel 000 refers to a portion of the display panel 000 other than the light-emitting unit 400. The display panel 000 also includes a first insulating layer 600 disposed on a sdie, away from the substrate 100, of the light-absorbing layer 300. In this way, the light-absorbing layer 300 in the display panel 000 is protected by the first insulating layer 600, such that the light-absorbing layer 300 is ensured not to be scratched, otherwise, the shielding effect of the light-absorbing layer 300 on the driving layer 200 deteriorates.

In the present disclosure, a plurality of second vias V2 in one-to-one correspondence with the plurality of first vias V1 are formed in the first insulating layer 600, and each of the second vias V2 in the first insulating layer 600 is communicated with the corresponding first via V1 in the light-absorbing layer 300. In this case, the plurality of light-emitting units 400 in the display panel 000 are distributed on a side, away from the substrate 100, of the first insulating layer 600. and the light-emitting units 400 are electrically connected to the pads S by the second vias V2 and the first vias V1.

Optionally, as shown in FIG. 4, at least a portion of the first insulating layer 600 extends into the first via V1, and the portion, extending into the first via V1, of the first insulating layer 600 covers at least a portion of an inner wall of the first via V1. In this case, the second via V2, communicated with the first via V1, is formed in the portion, extending into this first via V1, of the first insulating layer 600, and an orthographic projection of this second via V2 on the substrate 100 is within an orthographic projection of the corresponding first via V1 on the substrate 100. In this way, at least a portion of the inner wall of this first via V1 is protected by the portion, extending into the first via V1, of the first insulating layer 600.

Exemplarily, the inner wall of the first via V1 of the light-absorbing layer 300 is completely covered by the first insulating layer 600. That is, the portion, extending into the first via V1, of the first insulating layer 600 completely covers the inner wall of this first via V1. In this case, the light-absorbing layer 300 is covered at various locations by the first insulating layer 600, such that the light-absorbing layer 300 is ensured to be not exposed.

In some possible embodiments, the light-absorbing layer 300 in the display panel 000 typically includes charcoal particles. The charcoal particles allow the light-absorbing layer 300 to have a light-absorbing function. The display panel 000 needs to be immersed in an immersion gold bath during the preparation of the display panel 000, a solution (usually an acidic solution or an alkaline solution) in the immersion gold bath separates the charcoal particles out of the light-absorbing layer 300, which in turn contaminates the immersion gold bath. Therefore, to prevent the immersion gold bath from being contaminated, the portion, extending into the first via V1, of the first insulating layer 600 needs to completely cover the inner wall of the first via V1, such that the light-absorbing layer 300 is not exposed, and thus, in the case where the display panel 000 is immersed in the immersion gold bath, the solution within the immersion gold bath do not separate the carbon particles out of the light-absorbing layer 300, which ensures that the gold plating bath is not contaminated.

It should be noted that in the case where the light-absorbing layer 300 includes the charcoal particles, the light-absorbing layer 300 is typically made of an organic material. In other possible embodiments, the light-absorbing layer 300 is made of an inorganic material (e.g., a metal material). In the case where the light-absorbing layer 300 is made of the inorganic material, the portion, extending into the first via V1, of the first insulating layer 600 also needs to completely cover the inner wall of this first via V1 to ensure that the light-absorbing layer 300 is not exposed, such that in the case where the display panel 000 is immersed in the immersion gold bath, the solution in the immersion gold bath does not corrode a side surface of the light-absorbing layer 300, and thus the light-absorbing layer 300 has a better conductivity.

It should be noted that there are various types of the first insulating layer 600 in the display panel 000. For example, the first insulating layer 600 includes at least one of an inorganic insulating layer or an organic insulating layer. Here, when in a case where the first insulating layer 600 in the display panel 000 includes both the inorganic insulating layer 601 and the organic insulating layer 602, the second via V2 in the first insulating layer 600 includes a first sub-via V21 and a second sub-via V22 that are communicated. The first sub-via V21 is disposed in the inorganic insulating layer 601, and the second sub-via V22 is disposed in the organic insulating layer 602. The embodiments of the present disclosure give the description using the following four cases as examples.

In a first case, as shown in FIG. 4, in a case where the first insulating layer 600 in the display panel 000 is a single-layered film layer structure and the first insulating layer 600 is an inorganic insulating layer 601, a portion of the inorganic insulating layer 601 extends into the first via V1, and the portion, extending into the first via V1, of the inorganic insulating layer 601 completely covers the inner wall of the first via V1, such that the light-absorbing layer 300 is not exposed.

It should be noted that a portion, outside the first via V1, of the inorganic insulating layer 601 is in contact with a side, away from the substrate 100, of the light-absorbing layer 300. In this way, the portion, outside the first via V1, of the inorganic insulating layer 601 is capable of protecting the light-absorbing layer 300 from the side, away from the substrate 100, of the light-absorbing layer 300, and the portion, inside the first via V1, of the inorganic insulating layer 601 is capable of protecting the light-absorbing layer 300 from the inner wall of the first via V1. The inorganic insulating layer 601 has a better barrier to water and oxygen, and therefore, in a case where the light-absorbing layer 300 is protected and wrapped by the inorganic insulating layer 601, the protection effect on the light-absorbing layer 300 is effectively improved.

In a second case, as shown in FIG. 5, FIG. 5 is a schematic diagram of a film layer structure of a driving backplane in another display panel according to some embodiments of the present disclosure. In a case where the first insulating layer 600 in the display panel 000 is a single-layered film layer structure and the first insulating layer 600 is an organic insulating layer 602, a portion, extending into the first via V1, of the organic insulating layer 602 is capable of completely covering the inner wall of the first via V1, such that the light-absorbing layer 300 is not exposed.

It should be noted that a portion, outside the first via V1, of the organic insulating layer 602 is in contact with a side, away from the substrate 100, of the light-absorbing layer 300. In this way, the portion, outside the first via V1, of the organic insulating layer 602 is capable of protecting the light-absorbing layer 300 from the side, away from the substrate 100, of the light-absorbing layer 300, and the portion, inside the first via V1 of the organic insulating layer 602 is capable of protecting the light-absorbing layer 300 from the inner wall of the first via V1. Because the organic insulating layer 602 is well adhered to the light-absorbing layer 300, the portion, extending into the first via V1, of the organic insulating layer 602 is tightly fitted to the inner wall of the first via V1.

In addition, the organic insulating layer 602 has a good planarization, and thus in a case where the organic insulating layer 602 is provided on the side, away from the substrate 100, of the light-absorbing layer 300, the planarization of the side, away from the substrate 100, of the organic insulating layer 602 is good. In this case, the side, away from the substrate 100, of the organic insulating layer 602 is the outermost side of the driving backplane. Therefore, during subsequently forming the plurality of light-emitting units 400 on the driving backplane, surfaces, away from the substrate 100, of the respective light-emitting units 400 are flush, such that the display effect of the display panel 000 is good.

In a third case, as shown in FIG. 6, FIG. 6 is a schematic diagram of a film layer structure of a driving backplane in yet another display pane according to some embodiments of the present disclosure. In a case where the first insulating layer 600 in the display panel 000 is a double-layered film layer structure, i.e., the first insulating layer 600 includes both the inorganic insulating layer 601 and the organic insulating layer 602, and the inorganic insulating layer 601 is closer to the light-absorbing layer 300 with respect to the organic insulating layer 602, a portion of the inorganic insulating layer 601 extends into the first via V1 and covers the inner wall of the first via V1, and/or, a portion of the organic insulating layer 602 extends into the first via V1 and covers the inner wall of the first via V1.

Exemplarily, in FIG. 6, each of the inorganic insulating layer 601 and the organic insulating layer 602 has the portion extending into the first via V1, the portion, extending into the interior of the first via V1, of the inorganic insulating layer 601 is capable of completely covering the inner wall of the first via V1, and the portion, extending into the first via V1, of the organic insulating layer 603 is capable of completely covering a portion, away from the interior of the first via V1, of the inorganic insulating layer 601. In this way, the light-absorbing layer 300 is not exposed.

It should be noted that a portion, outside the first via V1, of the inorganic insulating layer 601 is in contact with a side, away from the substrate 100, of the light-absorbing layer 300, and a portion, outside the first via V1, of the organic insulating layer 602 is in contact with a side, away from the substrate 100, of the inorganic insulating layer 601. In this way, the portions, outside the first via V1, of the inorganic insulating layer 601 and the organic insulating layer 602 are capable of protecting the light-absorbing layer 300 from the side, away from the substrate 100, of the light-absorbing layer 300, and the portions, within the first via V1, of the inorganic insulating layer 601 and the organic insulating layer 602 are capable of protecting the light-absorbing layer 300 from the inner wall of the first via V1.

In addition, the organic insulating layer 602 has a good planarization, and thus in a case where the organic insulating layer 602 is disposed on a side, away from the substrate 100 of the inorganic insulating layer 601, the planarization of the side, away from the substrate 100, of the organic insulating layer 602 is good. In this case, the side, away from the substrate 100, of the organic insulating layer 602 is the outermost side of the driving backplane. Therefore, during subsequently forming the plurality of light-emitting units 400 on the driving backplane, surfaces, away from the substrate 100, of the respective light-emitting units 400 are flush, such that the display effect of the display panel 000 is good.

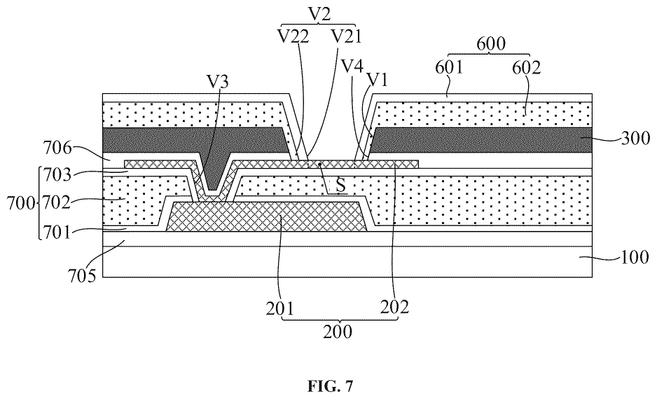

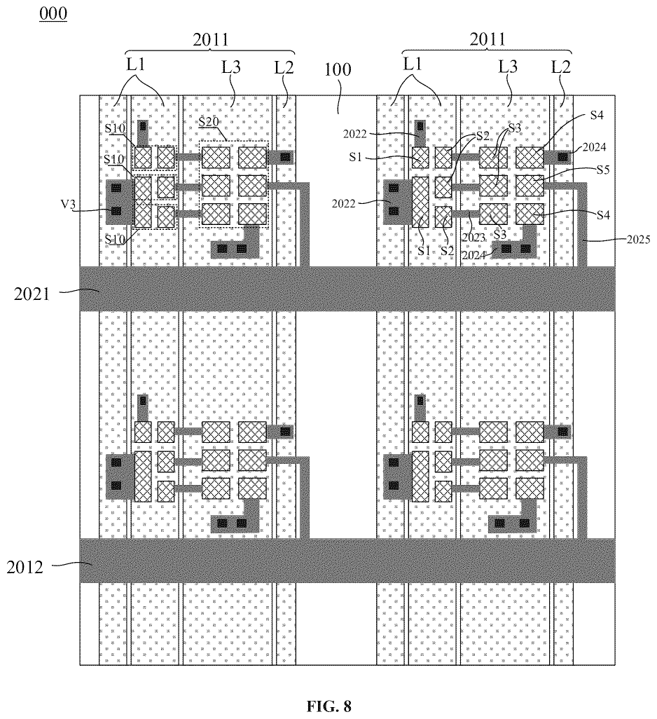

In a fourth case, as shown in FIG. 7, FIG. 7 is a schematic diagram of a film layer structure of a driving backplane in yet still another display panel according to some embodiments of the present disclosure. In a case where the first insulating layer 600 in the display panel 000 is a double-layered film layer structure, i.e., the first insulating layer 600 includes both the inorganic insulating layer 601 and the organic insulating layer 602, and the organic insulating layer 602 is closer to the light-absorbing layer 300 with respect to the inorganic insulating layer 601, a portion of the organic insulating layer 602 extends into the first via V1 and covers the inner wall of the first via V1, and/or a portion of the inorganic insulating layer 601 extends into the first via V1 and covers the inner wall of the first via V1.

Exemplarily, in FIG. 7, each of the organic insulating layer 602 and the inorganic insulating layer 601 has the portion extending into the first via V1, the portion, extending into the first via V1, of the organic insulating layer 602 is capable of completely covering the inner wall of the first via V1, and the portion, extending into the first via V1, of the inorganic insulating layer 601 is capable of completely covering a portion, away from the interior of the first via V1, of the organic insulating layer 602. In this way, the light-absorbing layer 300 is not exposed.

It should be noted that a portion, outside the first via V1, of the organic insulating layer 602 is in contact with a side, away from the substrate 100, of the light-absorbing layer 300, and a portion, outside the first via V1, of the inorganic insulating layer 601 is in contact with a side, away from the substrate 100, of the organic insulating layer 602. In this way, the portions, outside the first via V1, of the organic insulating layer 602 and the inorganic insulating layer 601 are capable of protecting the light-absorbing layer 300 from the side, away from the substrate 100, of the light-absorbing layer 300, and the portions, within the first via V1, of the organic insulating layer 602 and the inorganic insulating layer 601 are capable of protecting the light-absorbing layer 300 from the inner wall of the first via V1.

Here, because the organic insulating layer 602 is well adhered to the light-absorbing layer 300, the portion, extending into the first via V1, of the organic insulating layer 602 is tightly attached to the inner wall of the first via V1. Moreover, the inorganic insulating layer 601 has a better water-oxygen barrier ability, and thus in a case where the organic insulating layer 602 is covered by the inorganic insulating layer 601, the water and oxygen in the external environment are prevented from eroding the internal structures in the display panel 000. In this way, the protection effect on the light-absorbing layer 300 is further improved.

The following embodiments compare the reflectivity of the driving backplane to light in the second to fourth cases described above with the reflectivity of the driving backplane to light in the related art. Table 2 shows a comparison of the driving backplane in the present disclosure with the driving backplane in the related art, referring to Table 2.

TABLE 2

| | Reflectivity |
|---|---|
| Driving backplane in the related art | 35.52% |
| Driving backplane shown in FIG. 5 | 10.03% |
| Driving backplane shown in FIG. 6 | 12.09% |
| Driving backplane shown in FIG. 7 | 15.18% |

According to Table 2, in a case where the light-absorbing layer 300 is provided within the driving backplane, the metal signal lines in the driving layer 200 are better shielded by the light-absorbing layer 300, such that the light directed to the driving backplane is less reflected by the metal signal lines in the driving layer 200.

Optionally, a thickness of the light-absorbing layer 300 in the above embodiments ranges from 0.5 microns to 5 microns. Here, the greater the thickness of the light-absorbing layer 300, the greater the absorbance of light by the light-absorbing layer 300.

In some embodiments of the present disclosure, an optical density (OD) value of the light-absorbing layer 300 in the above embodiments is greater than or equal to 4. The OD value of the light-absorbing layer 300 herein is configured to represent an absorption degree of light by the light-absorbing layer 300. The larger the OD value of the light-absorbing layer 300, the larger the absorbance of the light by the light-absorbing layer 300.

Optionally, as shown in FIGS. 4 to 7, the driving layer 200 in the display panel 000 includes a first metal layer 201 and a second metal layer 202 that are stacked. The first metal layer 201 is closer to the substrate 100 relative to the second metal layer 202.

The first metal layer 201 includes a plurality of first driving signal lines (not marked in the figures). The second metal layer 202 includes a second driving signal line (not marked in the figures) and a plurality of conductive pads S. An extension direction of each of the first driving signal lines is intersected with an extension direction of each of the second driving signal lines. For example, the extension direction of the first driving signal line is perpendicular to the extension direction of the second driving signal line.

In the plurality of conductive pads S within the second driving layer 202, one portion of the conductive pads S needs to be electrically connected to the second driving signal lines, and the other portion of the conductive pads S needs to be electrically connected to the first driving signal lines.

In some embodiments of the present disclosure, the display panel 000 further includes a second insulating layer 700 disposed between the first metal layer 201 and the second metal layer 202. The first metal layer 201 and the second metal layer 202 are insulated by the second insulating layer 700, such that short circuits are avoided at locations where the first driving signal lines in the first metal layer 201 are intersected with the second driving signal lines in the second metal layer 202.

Exemplarily, a third via V3 is formed in the second insulating layer 700, such that a partial structure in the second metal layer 202 is electrically connected to a partial structure in the first metal layer 201 by the third via V3.

Optionally, the second insulating layer 700 in the display panel 000 includes a first inorganic protecting layer 701, an organic planarization layer 702, and a second inorganic protecting layer 703 that are stacked along a direction perpendicular to and away from the substrate 10. The first inorganic protecting layer 701 covers the first metal layer 201, and a third sub-via is formed in the first inorganic protecting layer 701. The organic planarization layer 702 is disposed on a side, away from the substrate 100, of the first inorganic protecting layer 701, and a fourth sub-via communicated with the third sub-via is formed in the organic planarization layer 702. The second inorganic insulating layer 703 is disposed on a side, away from the substrate 100, of the organic planarization layer 702, and a portion of the second inorganic insulating layer 703 extends into the third sub-via and the fourth sub-via and is capable of covering inner walls of the third sub-via and the fourth sub-via. A fifth sub-via is formed in the portion, extending into the third sub-via and the fourth sub-via, of the second inorganic insulating layer 703. Accordingly, the third sub-via, the fourth sub-via, and the fifth sub-via that are communicated with each other are capable of forming the third via V3 of the second insulating layer 700.

It should be noted that water and oxygen in the external environment are prevented by the first inorganic protecting layer 701, such that the water and oxygen in the external environment fail to erode the first metal layer 201 from the side, away from the substrate 100, of the first metal layer 201, and thus the probability of oxidative corrosion of the first metal layer 201 is effectively reduced.

The organic planarization layer 702 serves as a planarization role, such that the subsequent film layer structures are formed steadily.

For the second inorganic protecting layer 703, because the subsequent second metal layer 202 needs to be provided on the side, away from the substrate 100, of the second inorganic protecting layer 703, it is ensured by the second inorganic protecting layer 703 that water and oxygen in the external environment fail to erode the second metal layer 202 from the side, close to the substrate 100, of the second metal layer 202, such that the probability of oxidative corrosion of the metal layer 202 is effectively reduced.

Optionally, the display panel 000 further includes a third inorganic protecting layer 705 disposed on the side, close to the substrate 100, of the first metal layer 201, and a fourth inorganic protecting layer 706 disposed on the side, away from the substrate 100, of the second metal layer 202. Water and oxygen in the external environment are prevented by the third inorganic protecting layer 705 from eroding the first metal layer 201 from the side, close to the substrate 100, of the first metal layer 201, such that the probability of oxidative corrosion of the first metal layer 201 is further reduced. Water and oxygen in the external environment are prevented by the fourth inorganic protecting layer 706 from eroding the second metal layer 202 from the side, away from the substrate 100, of the second metal layer 202, such that the probability of oxidative corrosion of the second metal layer 202 is further reduced.

It should be noted that a fourth via V4 communicated with the second via V2 is formed in the fourth inorganic protecting layer 706, such that the light-emitting unit 400 is electrically connected to the conductive pad S in the second metal layer 202 after successively running through the second via V2 and the fourth via V4.

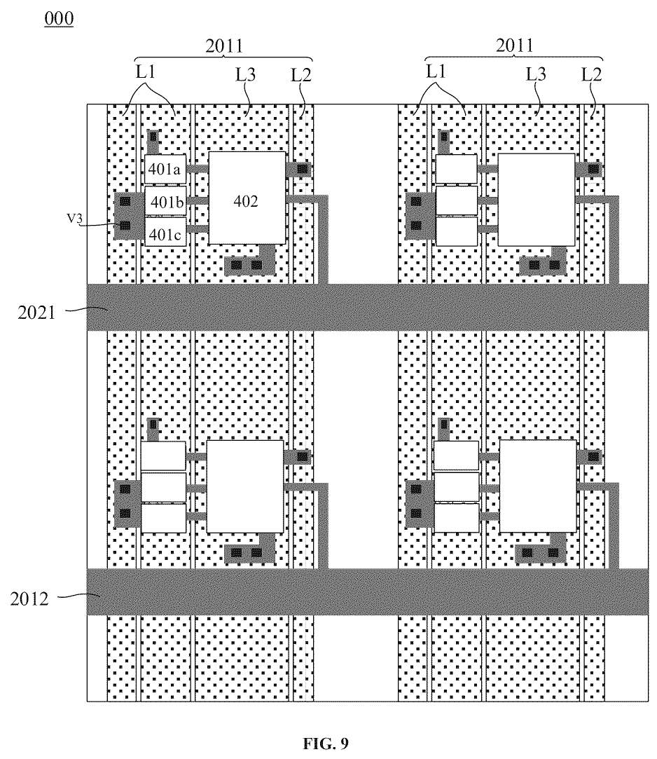

FIG. 8 is a partial top view of a driving backplane in a display panel according to some embodiments of the present disclosure. FIG. 9 is a partial top view of a display panel according to some embodiments of the present disclosure. Optionally, referring to FIG. 8 and FIG. 9, the light-emitting units 400 in the display panel 000 are arranged in a plurality of rows and columns. The plurality of first driving signal lines 2011 within the first metal layer 201 include a plurality of groups of first driving signal lines 2011 corresponding to the plurality of columns of light-emitting units 400, and each group of first driving signal lines 2011 is electrically connected to a corresponding column of light-emitting units 400. The plurality of second driving signal lines 2021 within the second metal layer 202 correspond to the plurality of rows of light-emitting units 400, and each second driving signal line 2021 is electrically connected to a corresponding row of light-emitting units 400. An orthographic projection of a row of light-emitting units 400 on the substrate 100 is overlapped with an orthographic projection of a corresponding group of first driving signal lines 2011 on the substrate 100, and a row of light-emitting units 400 is disposed between adjacent two second driving signal lines 2021.

Exemplarily, a group of first driving signal lines 2011 in the display panel 000 correspondingly connected to a row of light-emitting units 400 includes an anode driving signal line L1, a data signal line L2, and a grounding line L3. The second driving signal line 2021 correspondingly connected to a row of light-emitting units 400 is a power signal line.

The light-emitting units 400 in the display panel 000 include a driver chip 402 and at least one LED 401. In this case, the plurality of pads S distributed within the second metal layer 202 in the display panel 000 include a first pad group S10 configured to be fixedly connected to the LED 401 in the light-emitting unit 400, and a second pad group S10 configured to be fixedly connected to the driver chip 402 in the light-emitting unit 400. Optionally, an orthographic projection of the first pad group S10 on the substrate 100 is within an orthographic projection of the anode driving signal line L1 on the substrate 100, and an orthographic projection of the second pad group S20 on the substrate 100 is within an orthographic projection of the grounding line L3 on the substrate 100.

The first pad group S10 includes a first conductive pad S1 and a second conductive pad S2. The second pad group S20 includes a third conductive pad S3, a fourth conductive pad S4, and a fifth conductive pad S5.

One portion of a group of first driving signal lines 2011 electrically connected to the light-emitting units 400 is electrically connected to the first conductive pad S1 in the first pad group S10. For example, the second metal layer 202 further includes a first connecting electrode 2022. The anode driving signal line L1 of the group of first driving signal lines 2011 is electrically connected to the first conductive pad S1 by the first connecting electrode 2022.

The second conductive pad S2 in the first pad group S10 is electrically connected to the third conductive pad S3 in the second pad group S20. For example, the second metal layer 2022 also includes a second connecting electrode 2023. The first conductive pad S1 is electrically connected to the third conductive pad S3 by the second connecting electrode 2023.

The other portion of the group of first driving signal lines 2011 electrically connected to the light-emitting unit 400 is electrically connected to the fourth conductive pad S4 in the second pad group S20. For example, the second metal layer 2022 further includes a third connecting electrode 2024. The data signal line L2 in the group of first driving signal lines 2011 is electrically connected to one fourth conductive pad S4 by one third connecting electrode 2024, and the grounding line L3 in the group of first driving signal lines 2011 is electrically connected to another fourth conductive pad S4 by another third connecting electrode 2024.

The second driving signal line 2021 electrically connected to the light-emitting unit 400 is electrically connected to the fifth conductive pad S5 in the second pad group S20. For example, the second metal layer 2022 further includes a fourth connecting electrode 2025. The second driving signal line 2021 is electrically connected to the fifth conductive pad S5 by the fourth connecting electrode 2025.

Exemplarily, the number of LEDs 401 in the light-emitting unit 400 is three, and these three LEDs 401 are a red LED 401a for emitting red light, a green LED 401b for emitting green light, and a blue LED 401c for emitting blue light. In this case, the number of the first pad group S10 is also three, and these three first pad groups S10 are each electrically connected to the red LED, the green LED 401b, and the blue LED 401c.

Each of the red LED 401a, the green LED 401b, and the blue LED 401c in the light-emitting units 400 has two weld pins, which are a positive weld pin and a negative weld pin, respectively.

The positive weld pin of the red LED 401a is welded to the first conductive pad S1 in the corresponding first pad group S10, such that the positive weld pin of the red LED 401a is connected to the corresponding anode driving signal line L1 by the first conductive pad S1. The negative weld pin of the red LED 401a is welded to the second conductive pad S2 in the corresponding first pad group S10.

The positive weld pin of the green LED 401b is welded to the first conductive pad S1 in the corresponding first pad group S10, such that the positive weld pin of the green LED 401b is connected to the corresponding anode driving signal line L1 by this first conductive pad S1. The negative weld pin of the green LED 401b is welded to the second conductive pad S2 in the corresponding first pad group S10.

The positive weld pin of the blue LED 401c is welded to the first conductive pad S1 in the corresponding first pad group S10, such that the positive weld pin of the blue LED 401c is connected to the corresponding anode driving signal line L1 by the first conductive pad S1. The negative weld pin of the blue LED 401c is welded to the second conductive pad S2 in the corresponding first pad group S10.

The driver chip 402 in the light-emitting unit 400 has six weld pins, which are a power signal input pin, a data signal input pin, a grounding pin, and three signal output pins corresponding to the three LEDs.

The three signal output pins of the driver chip 402 are welded to three third conductive pads S3 within the second pad group S20, respectively. Since the three third conductive pads S3 are electrically connected to three second conductive pads S2 in three first pad groups S10, the three signal output weld pins of the driver chip 402 are electrically connected to the negative weld pins of the three LEDs.

The power signal input weld pin of the driver chip 402 is welded to one fifth conductive pad S5 within the second pad group S20, such that this power signal input weld pin is connected to the power signal line (i.e., the second driving signal line 2021) by this fifth conductive pad S5.

The data signal input pin of the driver chip 402 is welded to one fourth conductive pad S4 within the second pad group S20, such that the data signal input pin is connected to the data signal line L2 by this fourth conductive pad S4.

The grounding pin of the driver chip 402 is welded to another fourth conductive pad S4 within the second pad group S20, such that this grounding pin is connected to the grounding line L3 by this fourth conductive pad S4.

In this case, in a case where the display panel 000 needs to control a light-emitting unit 400 to emit light, a power driving signal is applied to the power signal line within the display panel 000 that is electrically connected to this light-emitting unit 400, and a data driving signal is applied to the data signal line L2 that is electrically connected to this light-emitting unit 400. In this way, after the driver chip 402 in the light-emitting unit 400 receives the power driving signal by the power signal input pin, the driver chip 402 is operating. After the driver chip 402 receives the data signal by the data signal input pin, the driver chip 402 generates three cathode signals corresponding to the three LEDs based on the data signal. The three cathode signals are transmitted to the three LED negative weld pins by the three signal output pins. The positive weld pin of the LED is always accessed to an anode signal applied by the anode driving signal line L1. Therefore, after the LED receives the anode signal and the cathode signal, this LED is capable of emitting light of the corresponding intensity.

It should be noted that to simplify the wiring structure within the display panel 000, at least two of the positive weld pins of the red LED 401a, the green LED 401b, and the blue LED 401c are connected to the same anode driving signal line L1. The light-emitting characteristics of the red LED 401a differ significantly from those of the green LED 401b and those of the blue LED 401c, while the light-emitting characteristics of the green LED 401b are less different from those of the blue LED 401c. Therefore, the positive weld pin of the green LED 401b and the positive weld pin of the blue LED 401c are connected to the same anode driving signal line L1, and the positive weld pin of the red LED 401a is connected to a different anode driving signal line L1 from the green LED 401b and the blue LED 401c. In this case, the first conductive pad S1 welded to the positive weld pin of the green LED 401b and the first conductive pad S1 welded to the positive weld pin of the blue LED 401c are formed as a one-piece structure. That is, the positive weld pin of the green LED 401b and the positive weld pin of the blue LED 401c are welded to the same first conductive pad S1, while the positive weld pin of the red LED 401a is welded to another first conductive pad S1.

For the light-absorbing layer 300 in the above embodiments, this light-absorbing layer 300 is made of either an organic material or a metal material with conductive properties. The embodiments of the present disclosure give the description using the following two optional embodiments as examples.

In a first optional embodiment, the light-absorbing layer 300 in the display panel 000 includes an organic film layer made of an organic material having light-absorbing properties. Exemplarily, this organic material is a black matrix (BM) material. That is, the light-absorbing layer 300 is made of the BM material. The BM material has a good light absorption, and thus in a case where the light-absorbing layer 300 is made of the BM material, the light-absorbing layer 300 has a higher degree of absorption of the ambient light directed to the display panel 000, such that the reflectivity of the display panel 000 to the ambient light is effectively reduced by the light-absorbing layer 300. For example, the BM material includes an organic resin material and a plurality of carbon particles dispersed within the organic resin material. Here, by adjusting the concentration of the carbon particles filled in the organic resin material. By adjusting the concentration of carbon particles filled in the organic resin material, the degree of light absorption by the BM material is adjusted.

It should be noted that the display panel 000 in the present disclosure serves as a spliced display unit in a spliced screen. In this way, after a plurality of display panels 000 are spliced together, a spliced display screen with a larger size is acquired. In the case where the display panel 000 serves as the spliced display unit, a width of a frame of the display panel 000 needs to be narrow. Therefore, in the present disclosure, the driving assembly is bonded to the display panel 000 by back bonding.

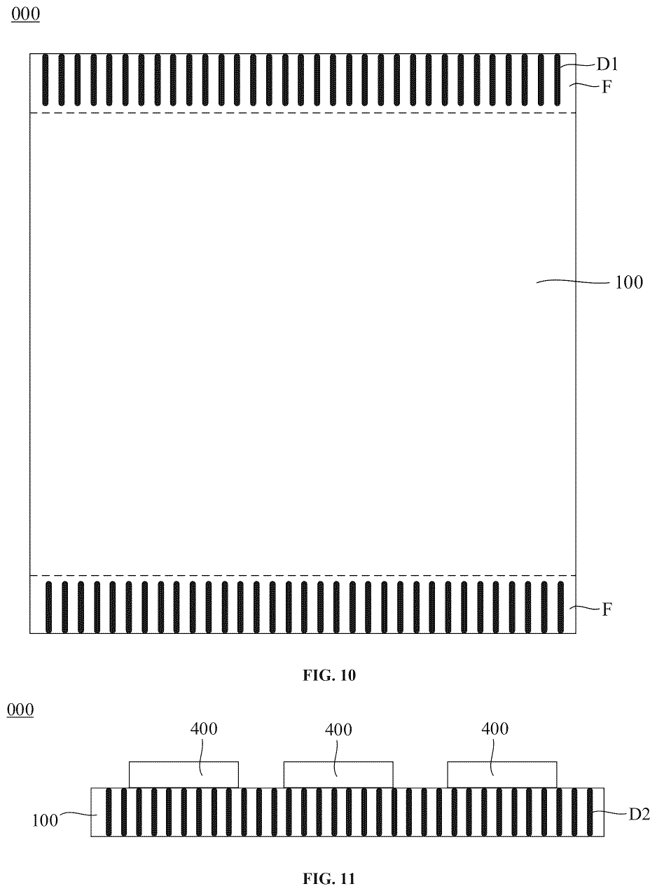

FIG. 10 is a backside schematic diagram of a display panel according to some embodiments of the present disclosure. Exemplarily, as shown in FIG. 10, an edge driver on a surface, away from the driving layer 200, of the substrate 100 in the display panel 000 includes a bonding region F. The display panel 000 also includes a plurality of signal leads D1 within the bonding region F. At least a portion of the plurality of signal leads D1 are electrically coupled to the plurality of first driving signal lines 2011. Exemplarily, one portion of the plurality of signal leads D1 are electrically connected to the plurality of first driving signal lines 2011 in the first metal layer 201, and the other portion of the plurality of signal leads D1 are electrically connected to the plurality of second driving signal lines 2021 in the second metal layer 202. It should be noted that the plurality of signal leads D1 in the bonding region F are configured to be bonded and connected to the driving assembly, such that the driving assembly is bonded to the display panel 000. In this way, the driving assembly is capable of transmitting driving signals to the first driving signal line 2011 and the second driving signal line 2021 by the signal leads D1, and thus the corresponding light-emitting unit 400 is lit. Here, the driving assembly is bonded to the back side of the display panel 000. In this way, the driving assembly does not take up space on the front side of the display panel 000, such that a screen-to-body ratio of the front side of the display panel 000 is high, and thus the width of the frame of the display panel 000 is narrow.

The second driving signal lines 2021 arranged horizontally are changed to be arranged longitudinally on the left and right sides of the display panel 000. In this way, a portion, arranged at the middle, of the plurality of signal leads D1 are electrically connected to the plurality of first driving signal lines 2011, and a portion, arranged at the sides, of the plurality of signal leads D1 are electrically connected to the second driving signal lines 2021 that are changed to be arranged in the longitudinal direction.

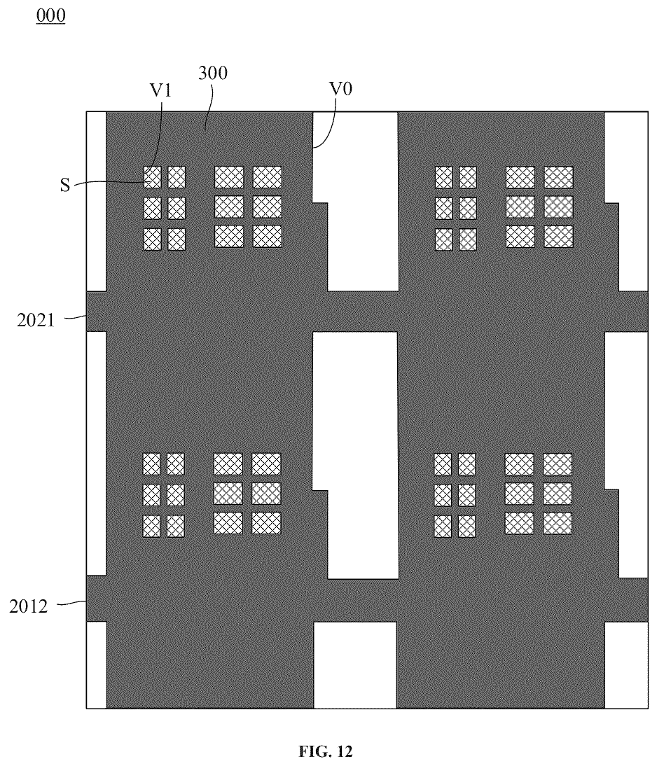

FIG. 11 is a side schematic diagram of the display panel illustrated in FIG. 10. Exemplarily, referring to FIG. 11, the display panel 000 further includes a plurality of connecting traces D2 correspondingly electrically connected to the plurality of signal leads D1. One portion of the connecting traces D2 are disposed on the side, close to the driving layer 200, of the substrate 100, and this portion of the connecting traces D2 is electrically connected to the first driving signal line 2011 and the second driving signal line 2021. The other portion of the connecting traces D2 are disposed on a side surface of the substrate 100, and ends of this portion of the connecting traces D2 towards the back side of the display panel 000 are electrically connected to the corresponding signal leads D1.

The plurality of connecting traces D2 and the plurality of signal leads D1 are formed by the same process. For example, the plurality of connecting traces D2 and the plurality of signal leads D1 are formed simultaneously by a laser etching process. Exemplarily, after the driving backplane is prepared, a conductive layer is sputtered on bonding regions on the back side and the side surface of the driving backplane, and on an edge region of the front side of the driving backplane, and then a single laser etching process is performed on the conductive layer, such that the plurality of connecting traces D2 and the plurality of signal leads D1 are formed simultaneously.

It should be noted that in the process of forming the plurality of signal leads D1 in the bonding region F by using the laser etching process, it is necessary to use a laser to irradiate the bonding region F. During the process, the laser irradiates a portion, covered by the bonding region F, of the light-absorbing layer 300 after running through the substrate 100. In a case where this portion of the light-absorbing layer 300 is not covered by the metal signal lines in the driving layer 200, the light-absorbing layer 300 is very prone to undesirable phenomena such as bulging, resulting in a lower planarization of the light-absorbing layer 300. To reduce the probability of undesirable phenomena such as bulging occurring in the light-absorbing layer 300, the portion, irradiated by the laser, of the light-absorbing layer 300 of the display panel 000 needs to be cut out.

FIG. 12 is a partial top view of a display panel according to some embodiments of the present disclosure. Exemplarily, as shown in FIGS. 8 and 12, after the light-absorbing layer 300 in the display panel illustrated in FIG. 12 is removed, its structure is referred to the panel illustrated in FIG. 8. An auxiliary via V0 is formed in the portion, covered by the bonding region F, of the light-absorbing layer 300 of the display panel 000. In the present disclosure, the display panel 000 has a blank region, and the blank region of the display panel 000 refers to a region within the bonding region F that is not covered by the first metal layer 201 and the second metal layer 202. Here, an orthographic projection of the auxiliary via V0 on the substrate 100 is overlapped with an orthographic projection of the blank region on the substrate 100. After the auxiliary via V0 is formed in the light-absorbing layer 300, in the process of forming the plurality of signal leads D1 in the bonding region F by using the laser etching process, the laser light transmitting through the substrate 100 is capable of running through the auxiliary via V0, such that the probability of the laser light being directly irradiated on the light-absorbing layer 300 is reduced, and thus the probability of bulging occurring in the light-absorbing layer 300 is low.

It should be noted that the orthographic projection of the auxiliary via V0 of the light-absorbing layer 300 on the substrate 100 needs to be within the orthographic projection of the blank region on the substrate 100. In this case, the orthographic projection of the auxiliary via V0 formed in the light-absorbing layer 300 on the substrate 100 is coincident with the orthographic projection of the first metal layer 201 on the substrate 100, which is not coincident with the orthographic projection of the second metal layer 202 on the substrate 100. In this way, even if a portion of the light-absorbing layer 300 is cut out, the light-absorbing layer 300 is still capable of well shielding the first metal layer 201 and the second metal layer 202, such that the display panel 000 has a low reflectivity to ambient light. In addition, in the process of forming the plurality of signal leads D1 within the bonding region F by using the laser etching process, a portion, covered by the driving layer 200, of the light-absorbing layer 300 is not irradiated by the laser, and this portion of the light-absorbing layer 300 is not subject to the undesirable phenomenon such as bulging, and thus there is no need to perform a cutout treatment on this portion of the light-absorbing layer 300.

Exemplarily, the orthographic projection of the blank region on the substrate 100 is completely coincident with the orthographic projection of the auxiliary via V0 on the substrate 100. In this case, in the portion, covered by the bonding region F, of the light-absorbing layer 300, whatever is not covered by the driving layer 202 is cut out. In this way, it is ensured that no undesirable phenomenon of bulging occurs in the light-absorbing layer 300.

In some other possible embodiments, the orthographic projection of the blank region on the substrate 100 is within the orthographic projection of the auxiliary via V0 of the light-absorbing layer 300 on the substrate 100, which is not limited herein.

In a group of first driving signal lines 2011, a distance between adjacent two driving signal lines 2011 is small. For example, a distance between the anode driving signal line L1 and the data signal line L2 in a group of first driving signal lines 2011 is only about 15 microns. Therefore, in the process of forming the plurality of signal leads D1 in the bonding region F by using the laser etching process, even though the laser light still runs through the substrate 100 and irradiates on the light-absorbing layer 300 after running through a region between adjacent two driving signal lines 2011 in a group of first driving signal lines 2011, due to the small distance between the adjacent two driving signal lines 2011, the energy of the laser light running through the region between adjacent two driving signal lines 2011 in a group of first driving signal lines 2011 is small, such that even if the laser light is irradiated on the light-absorbing layer 300, the light-absorbing layer is not bulged. For this reason, there is no need to perform the cutout treatment on this portion of the light-absorbing layer 300. Further, a width of this portion of the light-absorbing layer 300 is small, and therefore, in a case where this portion of the light-absorbing layer 300 is not cut up, the difficulty of the process of the light-absorbing layer 300 is effectively reduced.

Exemplarily, as shown in FIG. 12, the auxiliary vias V0 in the light-absorbing layer 000 are distributed between at least adjacent two groups of first driving signal lines 2011 and adjacent two second driving signal lines 2012. It should be noted that, as shown in FIG. 8, the second driving signal line 2012 needs to be connected to the conductive pad in the second pad group S20 by the fourth connecting electrode 2025. To ensure that a parasitic capacitance generated between the fourth connecting electrode 2025 and the first driving signal line 2011 is small, it needs to be ensured that an overlapped area between the fourth connecting electrode 2025 and the first driving signal line 2011 is small. Therefore, a portion, arranged along a longitudinal direction, of the fourth connecting electrodes 2025 are not overlapped with the first driving signal line 2011, and this portion of the fourth connecting electrode 2025 are arranged on one side of a group of first driving signal lines 2011. In this way, between the adjacent two groups of first driving signal lines 2011 and the adjacent two second driving signal lines 2012, there are two communicated sub-vias, wherein a width of one of these two sub-vias is greater than a width of the other sub-via. Two groups of first driving signal lines 2011 are disposed on both sides of the sub-via with a larger width. The fourth connecting electrode 2025 is disposed on one side of the sub-via with a smaller width, and a group of first driving signal lines 2011 is disposed on the other side of the sub-via with a smaller width.

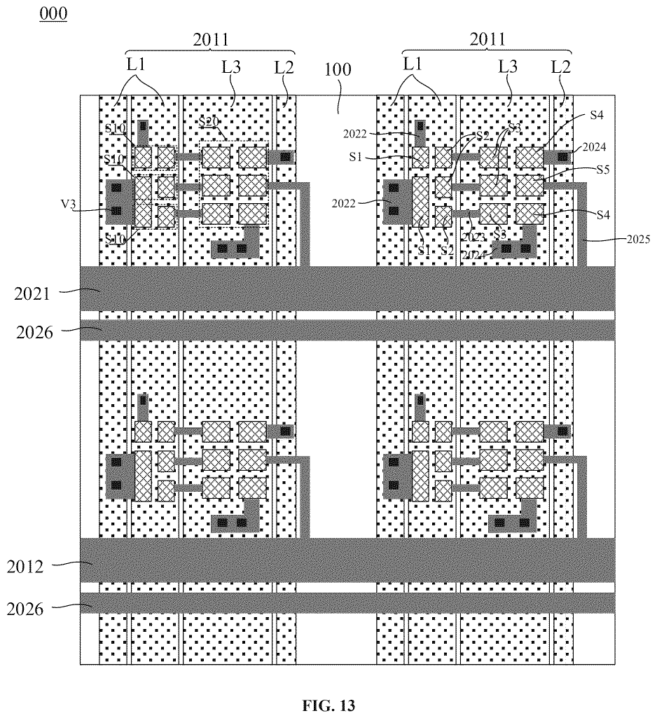

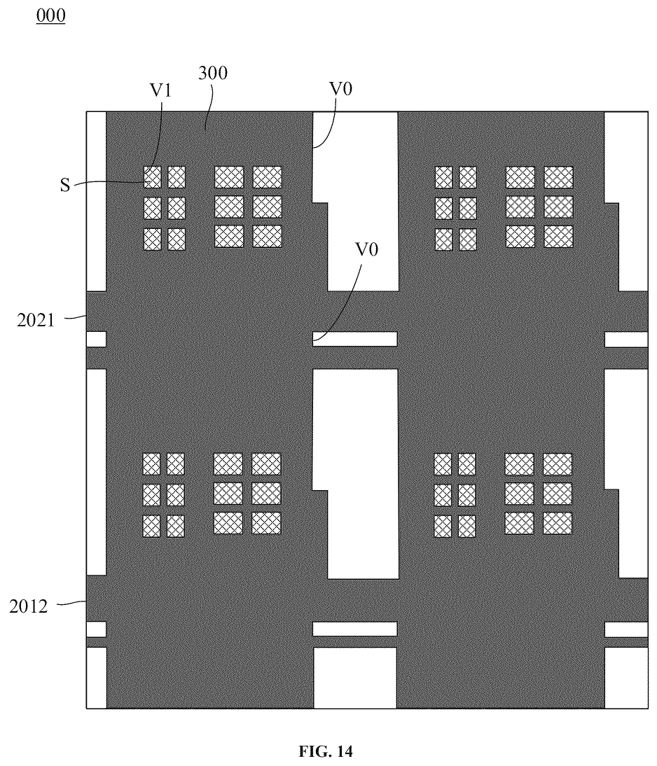

FIG. 13 is a partial top view of another display panel according to some embodiments of the present disclosure. FIG. 14 is a partial top view of the display panel illustrated in FIG. 13 with a light-absorbing layer removed. Optionally, as shown in FIG. 13 and FIG. 14, the second metal layer 202 in the display panel 000 includes auxiliary grounding lines 2026 arranged in parallel with the second driving signal lines 2011. Here, the auxiliary grounding line 2026 is electrically connected to the grounding line 2021 in the first metal layer 201, and an orthographic projection of the auxiliary grounding line 2026 on the substrate 100 is within the orthographic projection of the bonding region F on the substrate 100.

One of the auxiliary grounding lines 2026 and the adjacent second driving signal line 2021 are both distributed between two rows of light-emitting units 500. The auxiliary via V0 in the light-absorbing layer 300 is distributed between the adjacent two groups of first driving signal lines 2011 and one auxiliary grounding line 2026 and an adjacent second driving signal line 2021, in addition to adjacent two groups of first driving signal lines 2011 and adjacent two second driving signal lines 2012. In this way, the probability of the undesirable phenomenon of bulging occurring in the light-absorbing layer 300 is further reduced.

It should be noted that in the process of forming the plurality of signal leads D1 within the bonding region F by using the laser etching process, the laser light does not irradiate the region outside the bonding region F. Therefore, there is no need to form the auxiliary via V0 in the portion, not covered by the bonding region F, of the light-absorbing layer 300.

In a second optional embodiment, the light-absorbing layer 300 in the display panel 000 is conductive. That is, the light-absorbing layer 300 is made of a metal material.

FIG. 15 is a schematic diagram of a film layer structure of a light-absorbing layer according to some embodiments of the present disclosure. Exemplarily, referring to FIG. 15, the light-absorbing layer 300 in the display panel 000 includes a metal reflecting layer 301 and a first blackening layer 302 disposed on a side, away from the substrate 100, of the metal reflecting layer 301. The metal reflecting layer 301 is closer to the substrate 100 relative to the first blackening layer 302.

The metal reflecting layer 301 in the light-absorbing layer 300 is made of a metal material that has a high reflectivity to light. For example, the material of the metal reflecting layer 301 includes a molybdenum-niobium alloy. Thus, in the process of forming the plurality of signal leads D1 in the bonding region F by using the laser etching process, the laser light transmitting through the substrate 100 is irradiated on the metal reflecting layer 301 in the light-absorbing layer 300, such that the metal reflecting layer 301 is capable of reflecting the laser light, and then the undesirable phenomenon of bulging that occurs in the light-absorbing layer 300 after the light-absorbing layer 300 absorbs the energy of the laser light is effectively avoided.

The first blackening layer 302 in the light-absorbing layer 300 is made of a metal oxide material that has a high absorbance of light. For example, the material of the first blackening layer 302 includes molybdenum niobium oxynitride. In this way, a large portion of the ambient light directed to the display panel 000 is absorbed by the first blackening layer 302, such that the reflectivity of the display panel 000 to the ambient light is low.

In the present disclosure, in a case where the light-absorbing layer 300 includes a metal film layer made of a metal material having light-absorbing properties, the light-absorbing layer 300 also serves as a conductive structure in the display panel 000. Both the metal reflecting layer 301 and the first blackening layer 302 in the light-absorbing layer 300 have a low conductivity. Therefore, to ensure that the light-absorbing layer 300 better serves as the conductive structure in the display panel 000, the conductivity of the light-absorbing layer 300 needs to be increased. Exemplarily, the light-absorbing layer 300 further includes an auxiliary metal layer 303 disposed between the metal reflecting layer 301 and the first blackening layer 30. A conductivity of the auxiliary metal layer 303 is higher than a conductivity of the metal reflecting layer 301, and a reflectivity of the metal reflecting layer 301 is higher than a reflectivity of the auxiliary metal layer 303. In this way, by providing the metal reflecting layer 301 with the highest reflectivity on the side closest to the substrate 100, the laser light is better reflected; by providing the first blackening layer 302 with the highest absorbance on the side furthest away from the substrate 100, the ambient light is better absorbed; and by providing the auxiliary metal layer 303 with the highest conductivity between the metal reflecting layer 301 and the first blackening layer 302, the overall conductivity of the light-absorbing layer 300 is high, such that the light-absorbing layer 300 better serves as the conductive structure in the display panel 000.

It should be noted that the light-absorbing layer 300 is capable of serving as different conductive structures within the display panel 000 to achieve different functions. Embodiments of the present disclosure give the descriptions using the following two possible scenarios as examples.

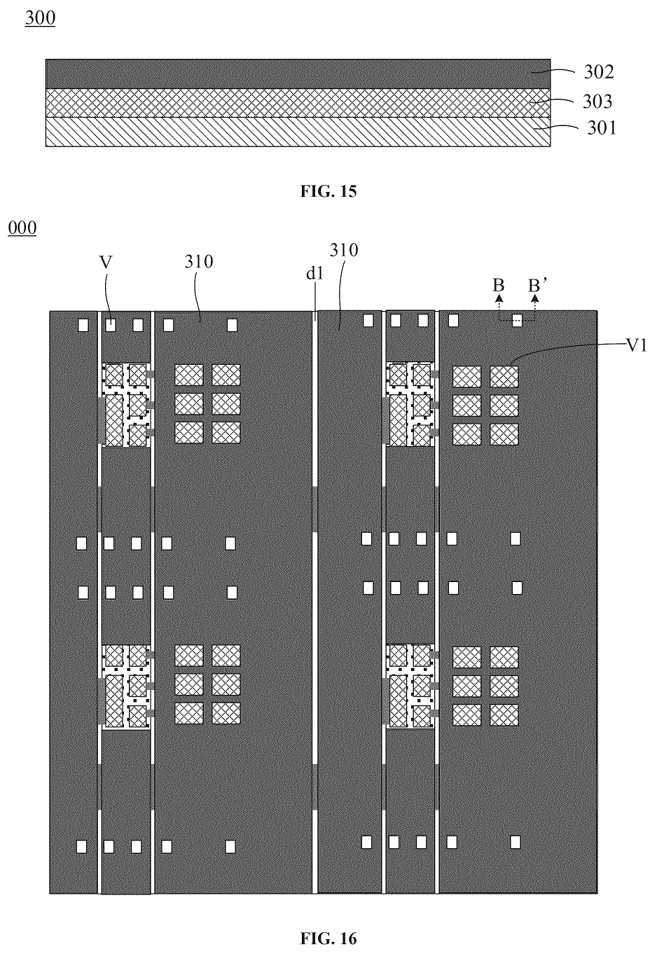

A first possible scenario is shown in FIG. 16, which is a partial top view of a display panel according to some embodiments of the present disclosure. After the light-absorbing layer 300 in the display panel illustrated in FIG. 16 is removed, the structure refers to the panel illustrated in FIG. 8. The light-absorbing layer 300 in the display panel 000 is divided into a plurality of auxiliary signal lines 310 corresponding to the plurality of first driving signal lines 2011 in the first metal layer 201. Here, an extension direction of each auxiliary signal line 310 is parallel to an extension direction of the corresponding first driving signal line 2012, and is connected in parallel to the corresponding first driving signal line 2012. A first gap d1 is present between adjacent two auxiliary signal lines 310. In this way, it is ensured that no short circuit occurs between adjacent two auxiliary signal lines 310. In this case, by connecting the auxiliary signal line 310 in parallel to each of the first driving signal lines 2012, the resistance of the first driving signal line 2012 is effectively lowered, such that the signal transmitted in the first driving signal line 2012 has substantially the same potential at various positions.

Exemplarily, the auxiliary signal line 310 corresponds to the anode driving signal line L1 and the grounding line L3 in the plurality of first driving signal lines 2011. In this way, the anode driving signal line L1 is connected in parallel to the corresponding auxiliary signal line 310, and the grounding line L3 is connected in parallel to the corresponding auxiliary signal line 310. Both the anode driving signal line L1 and the auxiliary signal line 310 transmit signals with fixed potentials, and therefore, in a case where both the anode driving signal line L1 and the auxiliary signal line 310 are connected in parallel to the corresponding auxiliary signal line 310, it is ensured that the potentials of the signal transmitted on the anode driving signal line L1 and the auxiliary signal line 310 are basically the same at the various positions, such that the driving layer 200 has a better driving effect on the light-emitting unit 400.

It should be noted that since a fourth inorganic protecting layer 706 is distributed between the light-absorbing layer 300 and the second metal layer 202, the light-absorbing layer 300 having the conductivity property is insulated from the second metal layer 202 by the fourth inorganic protecting layer 706, such that the auxiliary signal line 310 in the light-absorbing layer 300 and the second driving signal line in the second metal layer 202 2021 are not short-circuited to each other.

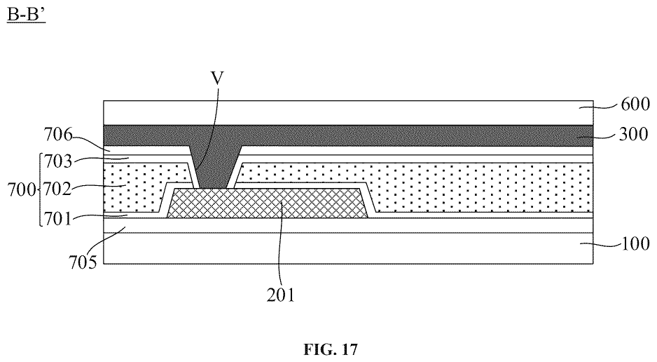

FIG. 17 is a schematic diagram of a film layer structure of the display panel illustrated in FIG. 16 along a line B-B′. In some embodiments of the present disclosure, referring to FIG. 17, a plurality of connecting vias V are formed in the display panel 000. The connecting via V runs successively through the fourth inorganic protecting layer 706 and the second insulating layer 700 in the display panel 000, such that the light-absorbing layer 300 with the conductivity property is connected to the first metal layer 201 by the connecting via V.

Exemplarily, the plurality of connecting vias V are distributed on at least two opposite sides of the plurality of auxiliary signal lines 310. One end of each auxiliary signal line 310 is electrically connected to the corresponding first driving signal line 2011 by at least one connecting via V, and the other end of each auxiliary signal line 310 is also electrically connected to the corresponding first driving signal line 2011 by at least one connecting via V. In this way, the corresponding first driving signal line 2011 and both ends of each auxiliary signal line 310 are connected in parallel.

In other possible embodiments, the connecting vias V are distributed on both sides of the respective light-emitting units 400 along an extension direction of the first driving signal line 310, such that the paralleled connection positions of the auxiliary signal line 310 with the first driving signal line 2011 are increased, and the resistance of the first driving signal line 2012 is further reduced.

In this case, an orthographic projection of the first pad group S10 on the substrate 100 is within an orthographic projection of one of the first driving signal lines 2011 on the substrate, and in an extension direction of the second driving signal line, a width of the first pad group S10 is approximately equal to a width of this first driving signal line 2011. Therefore, after the first via V1 corresponding to each conductive pad in the first pad group S10 is formed in the light-absorbing layer 300, this first via V1 makes the auxiliary signal line 310 corresponding to this first driving signal line 2011 disconnected. In the case where the connecting vias V are distributed on both sides of each light-emitting unit 400, even if the first via V1 makes the auxiliary signal line 310 disconnected, it is ensured that each segment of this auxiliary signal line 310 is connected in parallel to the first driving signal line 2011.

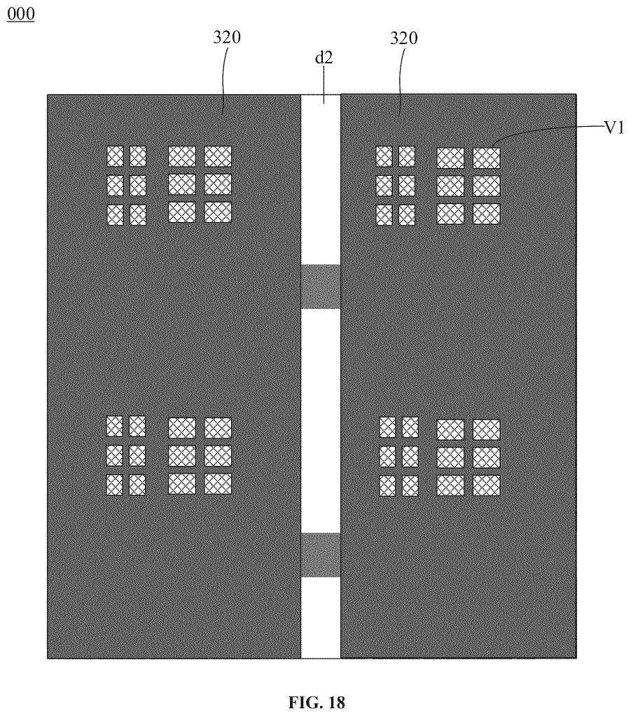

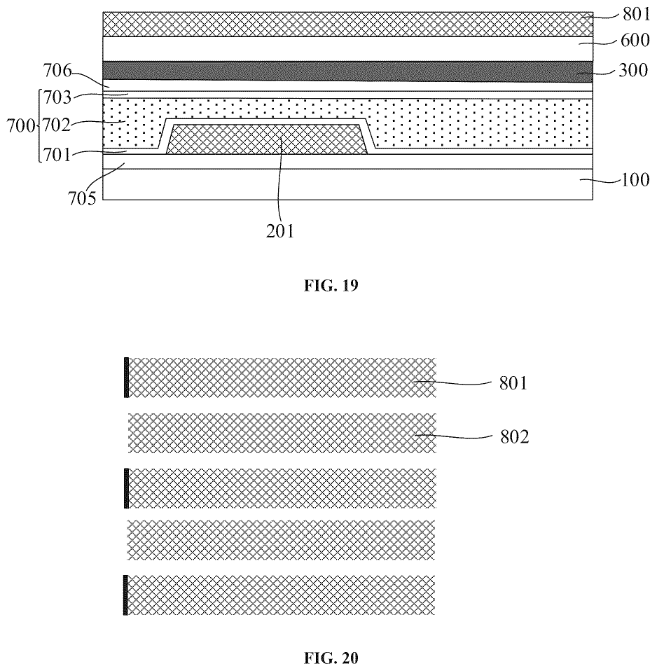

A second possible scenario is shown in FIGS. 18 and 19. FIG. 18 is a partial top view of another display panel according to some embodiments of the present disclosure. FIG. 19 is a schematic diagram of a film layer structure of the display panel illustrated in FIG. 18. In a case where the light-absorbing layer 300 in the display panel illustrated in FIG. 18 is removed, the structure is referred to the panel illustrated in FIG. 8. The light-absorbing layer 300 in the display panel 000 is divided into a plurality of first touch signal lines 320 arranged in parallel. A second gap d2 is present between adjacent two first touch signal lines 320. In this way, it is ensured that the adjacent two first touch signal lines 320 are not short-circuited.

The display panel 000 further includes a first insulating layer 600 disposed on the side, away from the substrate 100, of the light-absorbing layer 300, and a plurality of second touch signal lines 801 disposed on a side, away from the substrate 100, of the first insulating layer 600. To see the structures of the plurality of second touch signal lines 801 in the display panel 000 more clearly, reference is made to FIG. 20, which is a top view of a plurality of second touch signal lines according to some embodiments of the present disclosure. The plurality of second touch signal lines 801 are arranged in parallel, and an extension direction of each of the second touch signal lines 801 is intersected with an extension direction of each of the first touch signal lines 320. For example, the extension direction of the second touch signal line 801 is perpendicular to the extension direction of the first touch signal line 320.

One of the first touch signal line 320 and the second touch signal line 801 serves as a touch driving signal line and the other serves as a touch sensing signal line. Based on the cooperation of the touch driving signal line and the touch sensing signal line, the display panel 000 has a touch function.

It should be noted that the extension direction of the first touch signal line 320 is parallel to the extension direction of the first driving signal line 2011, and the extension direction of the second touch signal line 801 is parallel to the extension direction of the second driving signal line 2021. Here, an orthographic projection of one of the first touch signal lines 320 on the substrate 100 covers an orthographic projection of at least one row of light-emitting units 400 on the substrate 100. For example, in FIG. 19, the orthographic projection of one first touch signal line 320 on the substrate 100 covers the orthographic projections of adjacent two columns of light-emitting units 400 on the substrate 100.

Optionally, as shown in FIG. 20, at least a portion of the second touch signal lines 801 in the display panel 000 are grid-like metal signal lines. That is, a plurality of grid holes arranged in an array are formed in at least one portion of the second touch signal lines 801. For example, the array-arranged grid holes are formed in each portion of the second touch signal lines 801. In this case, the second touch signal line 600 is made of a metal material, which ensures that the second touch signal line 801 has a better conductivity. Moreover, in a case where the arrayed-arranged grid holes are formed in various portions of the second touch signal line 801, an area of the orthographic projection of the second touch signal line 801 on the substrate 100 is effectively reduced. In this way, even if a metal material is used to prepare this second touch signal line 801 and the second touch signal line 801 is away from the substrate 100 with respect to the light-absorbing layer 300, the reflectivity of the second touch signal line 801 to the ambient light is low, such that the reflectivity of the display panel 000 to the ambient light does not increase substantially.

Optionally, the display panel 000 further includes a virtual signal line 802 disposed between adjacent two second touch signal lines 801. An extension direction of the virtual signal line 802 is parallel to the extension direction of the second touch signal line 801, and at least a portion of the virtual signal lines 802 are grid-like metal signal lines. That is, grid holes arranged in an array are formed in at least a portion of the virtual signal lines 802. For example, the array-arranged grid holes are formed in each portion of the virtual signal lines 802. It should be noted that a distribution density of the grid holes in the virtual signal line 802 is equal to a distribution density of the grid holes in the second touch signal line 801. In this way, by providing the virtual signal line 802 between adjacent two second touch signal lines 801, the front side of the display panel 000 has an equal reflectivity to ambient light at all positions, such that the front side of the display panel 000 presents a better effect when the display panel 00 does not display images. It should be noted that in a case where a distance between adjacent two second touch signal lines 801 is small, it is not necessary to provide the virtual signal line 802 between adjacent two second touch signal lines 801.

In the present disclosure, the virtual signal line 802 and the second driving signal line 801 are disposed in the same layer and made of the same material. That is, the virtual signal line 802 and the second driving signal line 801 are formed by the same patterning process. In this way, the process difficulty of preparing the display panel 000 is effectively reduced.

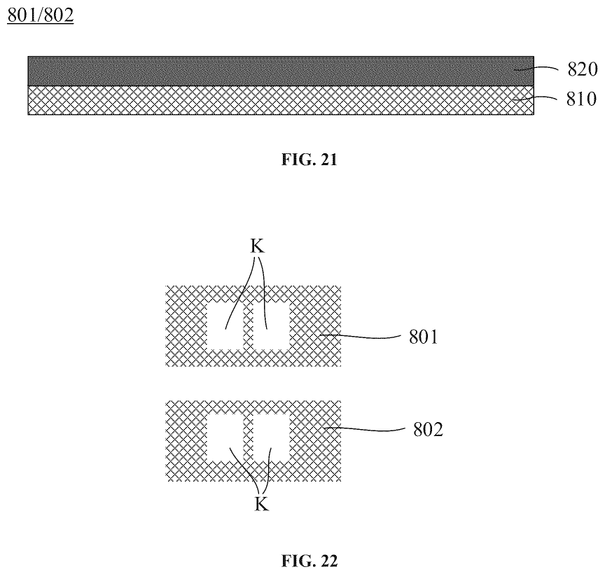

FIG. 21 is a schematic diagram of a film layer structure of a second touch signal line or a virtual signal line according to some embodiments of the present disclosure. Optionally, as shown in FIG. 21, at least one of the second touch signal line 801 or the virtual signal line 802 includes a conductive metal layer 810 and a second blackening layer 820 that are stacked. The conductive metal layer 810 is closer to the substrate 100 with respect to the second blackening layer 820. It should be noted that, since the second touch signal line 801 and the virtual signal line 802 are formed simultaneously by the same process, each of the second touch signal line 801 and the virtual signal line 802 includes the conductive metal layer 810 and the second blackening layer 820 that are stacked. in this way, the ambient light directed to the display panel 000 is absorbed by the second blackening layer 820, such that the reflectivity of the second touch signal line 801 and the virtual signal line 802 to the ambient light is further reduced.

FIG. 22 is a partially enlarged view of a second touch signal line and a virtual signal line according to some embodiments of the present disclosure. In some embodiments of the present disclosure, as shown in FIG. 22, a hollowed-out structure K is formed in at least one of the second touch signal line 801 or the virtual signal line 802. An orthographic projection of the hollowed-out structure K on the substrate 100 covers the orthographic projection of the first via V1 on the substrate 100. In this way, the light-emitting unit 400 is electrically connected to the conductive pad S after successively running through the hollowed-out structure K and the first via V1.

In summary, some embodiments of the present disclosure provide a display panel. The display panel includes the substrate, the driving layer, the light-absorbing layer, and the plurality of light-emitting units. The orthographic projection of the light-absorbing layer on the substrate is overlapped with the orthographic projection of the driving layer on the substrate. In this way, the light-absorbing layer is capable of absorbing the ambient light directed to the display panel, such that the ambient light directed to the display panel is reflected to a lower extent by the driving layer, and thus the display panel is ensured to have a lower reflectivity to the ambient light. In addition, the reflectivity of the display panel to the ambient light is reduced by providing the light-absorbing layer in the display panel. Therefore, by appropriately increasing the transmittance of the auxiliary light-absorbing layer disposed on the side, away from the substrate, of the plurality of light-emitting units, the auxiliary light-absorbing layer has a lower absorbance to the light, and thus the light emitted from the light-emitting units is absorbed to a lower extent by the auxiliary light-absorbing layer. In this way, the overall display brightness of the display panel is high without the need for the display panel to provide a large driving current to the light-emitting units, and thus the power consumption of the display panel is effectively reduced.

Some embodiments of the present disclosure further provide a display device. The display device may be a mobile phone, a tablet computer, a television, a monitor, a laptop computer, a digital photo frame, a navigator, or any other product or component with a display function. The display device includes a driving assembly and a display panel as described above. The driving assembly is electrically connected to a driving layer in the display panel, and the driving assembly is configured to provide a driving signal to a light-emitting unit by the driving layer.

It should be noted that in the accompanying drawings, the sizes of layers and regions may be exaggerated for clearer illustration. It should be understood that where an element or layer is referred to as being “on” another element or layer, the element or layer may be directly on another element, or intervening layers therebetween may be present. In addition, it should be understood that where an element or layer is referred to as being “under” another element or layer, the element or layer may be directly under the other element, or there may be more than one intervening layer or element. In addition, it may be further understood that in the case that a layer or element is referred to as being “between” two layers or two elements, the layer may be the only layer between the two layers or two elements, or more than one intervening layer or element may further be present. Like reference numerals indicate like elements throughout.

In the present disclosure, the terms “first” and “second” are only used for descriptive purposes, and cannot be understood as indicating or implying relative importance. The term “a plurality of” refers to two or more, unless expressly defined otherwise.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A display panel, comprising:
a substrate;
a driving layer disposed on a side of the substrate, wherein the driving layer comprises a plurality of conductive pads;
a light-absorbing layer disposed on a side, away from the substrate, of the driving layer, wherein an orthographic projection of the light-absorbing layer on the substrate is overlapped with an orthographic projection of the driving layer on the substrate, and a plurality of first vias corresponding to the plurality of conductive pads are formed in the light-absorbing layer, an orthographic projection of each of the first vias on the substrate is overlapped with an orthographic projection of a corresponding one of the conductive pads on the substrate; and
a plurality of light-emitting units disposed on a side, away from the substrate, of the light-absorbing layer, wherein the plurality of light-emitting units are electrically connected to at least a portion of the conductive pads by the first vias.

2. The display panel according to claim 1, wherein within a display region of the display panel, the orthographic projection of the light-absorbing layer on the substrate covers an orthographic projection of a portion, other than the conductive pads, of the driving layer on the substrate.

3. The display panel according to claim 1, further comprising: a first insulating layer disposed on the side, away from the substrate, of the light-absorbing layer, wherein a plurality of second vias in one-to-one correspondence with the plurality of first vias are formed in the first insulating layer, each of the second vias being communicated to a corresponding one of the first vias;
wherein each of the light-emitting units is electrically connected to the conductive pad by the second via and the first via.

4. The display panel according to claim 3, wherein
a portion of the first insulating layer extends into the first via and covers at least a portion of an inner wall of the first via; and
the first insulating layer comprises at least one of an inorganic insulating layer or an organic insulating layer.

5. The display panel according to claim 4, wherein
the light-absorbing layer comprises charcoal particles; and
the inner wall of the first via is completely covered by the first insulating layer.

6. The display panel according to claim 4, wherein
the first insulating layer comprises both the inorganic insulating layer and the organic insulating layer, the inorganic insulating layer being closer to the light-absorbing layer relative to the organic insulating layer; and
a portion of the inorganic insulating layer extends into the first via and covers the inner wall of the first via, and/or, a portion of the organic insulating layer extends into the first via and covers the inner wall of the first via.

7. The display panel according to claim 4, wherein
the first insulating layer comprises both the inorganic insulating layer and the organic insulating layer, the organic insulating layer being closer to the light-absorbing layer relative to the inorganic insulating layer; and
a portion of the inorganic insulating layer extends into the first via and covers the inner wall of the first via, and/or, a portion of the organic insulating layer extends into the first via and covers the inner wall of the first via.

8. The display panel according to claim 1, wherein a thickness of the light-absorbing layer ranges from 0.5 microns to 5 microns.

9. The display panel according to claim 1, wherein an optical density (OD) of the light-absorbing layer is greater than or equal to 4.

10. The display panel according to claim 1, wherein the driving layer comprises a first metal layer and a second metal layer that are stacked; and the display panel further comprises a second insulating layer disposed between the first metal layer and the second metal layer, the first metal layer being closer to the substrate relative to the second metal layer; wherein
the first metal layer comprises a plurality of first driving signal lines, and the second metal layer comprises a second driving signal line and the plurality of conductive pads, wherein an extension direction of each of the first driving signal lines is intersected with an extension direction of the second driving signal line; and
in the plurality of conductive pads, a portion of the conductive pads is electrically connected to the second driving signal line, and another portion of the conductive pads is electrically connected to the first driving signal line.

11. The display panel according to claim 10, wherein the light-absorbing layer comprises an organic film layer made of an organic material with a light-absorbing property.

12. The display panel according to claim 11, wherein an edge region of a side, away from the driving layer, of the substrate comprises a bonding region, and the display panel further comprises a plurality of signal leads disposed in the bonding region, at least a portion of the plurality of signal leads being electrically connected to the plurality of first driving signal lines;
wherein an auxiliary via is formed in a portion, covered by the bonding region, of the light-absorbing layer; the display panel comprises a blank region, wherein the blank region is a region, not covered by the first metal layer and the second metal layer, within the bonding region; and an orthographic projection of the auxiliary via on the substrate is overlapped with an orthographic projection of the blank region on the substrate.

13.-15. (canceled)

16. The display panel according to claim 11, further comprising: a plurality of connecting traces correspondingly electrically connected to the plurality of signal leads, wherein one portion of the plurality of connecting traces is disposed on a side, close to the driving layer, of the substrate, and the other portion of the plurality of connecting traces is disposed on a side surface of the substrate;
wherein the plurality of connecting traces and the plurality of signal leads are formed by a same process.

17. The display panel according to claim 8, wherein
the light-absorbing layer is conductive; and
the light-absorbing layer comprises a metal reflecting layer, and a first blackening layer is disposed on a side, away from the substrate, of the metal reflecting layer.

18. The display panel according to claim 17, wherein the light-absorbing layer comprises a plurality of auxiliary signal lines corresponding to the plurality of first driving signal lines, wherein a first gap is present between adjacent two of the auxiliary signal lines, each of the auxiliary signal lines and a corresponding one of the first driving signal lines extends along a same direction, each of the auxiliary signal lines is connected in parallel with a corresponding one of the first driving signal lines.

19. (canceled)

20. The display panel according to claim 17, wherein
the light-absorbing layer comprises a plurality of first touch signal lines arranged in parallel, a second gap being present between adjacent two of the first touch signal lines; and
the display panel further comprises a first insulating layer disposed on the side, away from the substrate of the light-absorbing layer, and a plurality of second touch signal lines disposed on a side, away from the substrate, of the first insulating layer, wherein an extension direction of each of the second touch signal lines is intersected with an extension direction of each of the first touch signal lines.

21.-24. (canceled)

25. The display panel according to claim 17, wherein the light-absorbing layer further comprises an auxiliary metal layer disposed between the metal reflecting layer and the first blackening layer, wherein a conductivity of the auxiliary metal layer is greater than a conductivity of the metal reflecting layer, and a reflectivity of the metal reflecting layer is greater than a reflectivity of the auxiliary metal layer.

26. The display panel according to claim 11, further comprising: a plurality of driver chips, wherein the plurality of driver chips are electrically connected to one or more of the light-emitting units;
wherein the plurality of conductive pads comprise a first pad group configured to be fixedly connected to the light-emitting units, and a second pad group configured to be fixedly connected to the driver chips.

27. The display panel according to claim 26, wherein the first pad group comprises a first conductive pad and a second conductive pad, and the second pad group comprises a third conductive pad, a fourth conductive pad, and a fifth conductive pad;
wherein one portion of the plurality of first driving signal lines is electrically connected to the first conductive pad, the second conductive pad is electrically connected to the third conductive pad, another portion of the plurality of first driving signal lines is electrically connected to the fourth conductive pad, and the second driving signal line is electrically connected to the fifth conductive pad.

28. (canceled)

29. A display device, comprising: a driving assembly and a display panel; wherein
the display panel, comprises:
a substrate;
a driving layer disposed on a side of the substrate, wherein the driving layer comprises a plurality of conductive pads;
a light-absorbing layer disposed on a side, away from the substrate, of the driving layer, wherein an orthographic projection of the light-absorbing layer on the substrate is overlapped with an orthographic projection of the driving layer on the substrate, and a plurality of first vias corresponding to the plurality of conductive pads are formed in the light-absorbing layer, an orthographic projection of each of the first vias on the substrate is overlapped with an orthographic projection of a corresponding one of the conductive pads on the substrate; and
a plurality of light-emitting units disposed on a side, away from the substrate, of the light-absorbing layer, wherein the plurality of light-emitting units are electrically connected to at least a portion of the conductive pads by the first vias; and
the driving assembly is electrically connected to the driving layer, and the driving assembly is configured to provide driving signals to the light-emitting units through the driving layer.
